(19) United States
(12) Patent Application Publication
(10) Pub. No.: US 2026/0206233 A1
(43) Pub. Date: Jul. 16, 2026

(54) EPITAXIALLY-GROWN MEMORY DEVICE AND MAKING AN EPITAXIALLY-GROWN DEVICE ON CMOS

(71) Applicant: Government of the United States of America, as represented by the Secretary of Commerce, Gaithersburg, MD (US)

(72) Inventors: Daniel Bernard Gopman, Gaithersburg, MD (US); Gina Cristina Adam, Washington, DC (US); Brian Douglas Hoskins, Washington, DC (US); Jenae Elizabeth Shoup, Germantown, MD (US)

(21) Appl. No.: 19/485,233

(22) PCT Filed: Apr. 15, 2024
(86) PCT No.: PCT/US2024/024653

§ 371 Date: Nov. 17, 2025

Related U.S. Application Data
(60) Provisional application No. 63/459,283, filed on Apr. 14, 2023.

(51) Int. Cl. H10B 61/00; H10N 50/01; H10N 50/10; H10N 50/85

(52) U.S. Cl. CPC H10B 61/10; H10N 50/01; H10N 50/10; H10N 50/85

(57) ABSTRACT

An epitaxially-grown memory device includes: a CMOS wafer; a plurality of contact electrodes making electrical contact to metallized VIAs and disposed at a surface of the CMOS wafer; a bottom electrode contact making electrical contact to one of the plurality of contact electrodes and also disposed at the surface of the CMOS wafer; a rock salt layer formed above the bottom electrode; a buffer layer grown above the rock salt layer; an epitaxial functional layer grown above the buffer layer; a top electrode contact grown above the epitaxial functional layer and configured to convey electrical signals to one of the plurality of contact electrodes; and an insulating dielectric formed between the top electrode contact and the bottom electrode contact.

### CROSS REFERENCE TO RELATED APPLICATIONS

This application is a national stage application, filed under 35 U.S.C. § 371, of International Patent Application No. PCT/US24/24653, filed on Apr. 15, 2024, which is incorporated by reference herein in its entirety, which claim the benefit of U.S. Provisional Patent Application Ser. No. 63/459,283 (filed Apr. 14, 2023), which is herein incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### BACKGROUND

The present invention generally relates to the field of semiconductor devices, and more particularly to techniques for epitaxial growth of functional materials on CMOS wafers.

Semiconductor devices have revolutionized various fields, including computing, communication, and sensing. Complementary metal-oxide-semiconductor (CMOS) technology has been the workhorse of the semiconductor industry, enabling the fabrication of highly integrated circuits with billions of transistors on a single chip. However, conventional CMOS technology faces challenges in meeting the increasing demand for advanced functionalities, such as spintronics, ferroelectrics, and resistive switching.

Spintronic materials, which exploit the spin of electrons in addition to their charge, offer promising applications in areas such as magnetic sensors, non-volatile memory, and quantum computing. Ferroelectric materials, characterized by their spontaneous electric polarization that can be switched by an external electric field, find applications in ferroelectric random access memory (FeRAM) and piezoelectric devices. Resistive switching materials, which exhibit reversible changes in resistance under applied voltage or current, are essential for memristors and neuromorphic computing.

Integrating these functional materials with CMOS technology has been a significant challenge due to the lattice mismatch and thermal expansion coefficient mismatch between the materials and the silicon substrate. Direct growth of these materials on silicon often leads to poor crystal quality, resulting in degraded device performance. Buffer layers are commonly used to bridge the mismatch, but they can introduce additional complexity and increase fabrication costs.

It is therefore an objective of the present invention to provide a method for epitaxial growth of functional materials on CMOS wafers with improved crystal quality and performance, thereby overcoming the above-mentioned disadvantages of the prior art at least in part.

Accordingly, methods and equipment for using epitaxial functional materials integrated with CMOS technology would be advantageous and would be favorably received in the art.

### BRIEF DESCRIPTION

One aspect of the present invention relates to an article. A CMOS wafer may be understood as a thin slice of semiconductor material, typically silicon, on which integrated circuits are fabricated. VIAs are vertical interconnect accesses that provide electrical connections between different layers of an integrated circuit. A rock salt layer is a crystalline layer with a crystal structure, e.g., a cubic cell, that can have, e.g., a face-centered cubic lattice. A buffer layer is an intermediate layer grown between two dissimilar materials to improve adhesion and reduce strain. An epitaxial functional layer is a crystalline layer with specific functionalities, such as spintronic, ferroelectric, or resistive switching properties, grown on top of another crystalline layer with a similar crystal structure.

It may be provided that the article comprises a CMOS wafer. This arrangement provides a foundation for integrating functional materials with established CMOS technology, enabling the development of novel devices with enhanced capabilities.

It may be provided that the article comprises a plurality of contact electrodes making electrical contact to metallized VIAs and disposed at a surface of the CMOS wafer. This arrangement facilitates electrical connections between the functional materials and the underlying CMOS circuitry, allowing for the control and readout of the device.

It may be provided that the article comprises a bottom electrode contact making electrical contact to one of the plurality of contact electrodes and also disposed at the surface of the CMOS wafer. This arrangement establishes a bottom electrical contact for the device, enabling the flow of current through the functional materials.

It may be provided that the article comprises a rock salt layer formed above the bottom electrode. One advantage of this arrangement is that the rock salt layer with its cubic crystal structure serves as a template for the subsequent growth of epitaxial functional layers with improved crystal quality and reduced defects. This leads to enhanced device performance. For example, in the case of spintronic materials, this can result in higher tunneling magnetoresistance and longer spin lifetimes. For ferroelectric materials, it can lead to higher polarization and more reliable switching behavior.

It may be provided that the article comprises a buffer layer grown above the rock salt layer. This arrangement further improves the crystal quality of the epitaxial functional layer by mitigating the lattice mismatch between the rock salt layer and the functional material. Additionally, the buffer layer can enhance adhesion between the layers, improving device reliability.

It may be provided that the article comprises an epitaxial functional layer grown above the buffer layer. This arrangement introduces the desired functionality, such as spintronics, ferroelectrics, or resistive switching, into the device. The epitaxial growth ensures that the functional layer inherits the crystal structure and orientation of the underlying layers, resulting in optimal device performance.

It may be provided that the article comprises a top electrode contact grown above the epitaxial functional layer and configured to convey electrical signals to one of the plurality of contact electrodes. This arrangement provides a top electrical contact for the device, completing the electrical circuit and enabling the operation of the device as a two-terminal device.

It may be provided that the article comprises an insulating dielectric formed between the top electrode contact and the bottom electrode contact. One advantage of this arrangement is that the insulating dielectric ensures electrical isolation between the top and bottom electrodes, preventing short circuits and enabling the proper functioning of the device. This also allows for the control of the current flow through the functional material, which is essential for achieving the desired device characteristics.

It may be provided that the rock salt layer is formed with a fiber texture. A fiber texture may be understood as a crystallographic orientation where the crystal grains have a preferred alignment along a specific direction, resembling the arrangement of fibers in a fabric. One advantage of this arrangement is that it can enhance the anisotropic properties of the functional materials, leading to improved performance in specific directions. For example, in spintronic devices, a fiber texture can promote spin transport along the fiber direction, reducing spin scattering and increasing spin diffusion lengths.

It may be provided that the rock salt layer is formed with a biaxial texture. A biaxial texture may be understood as a crystallographic orientation where the crystal grains have a preferred alignment along two orthogonal directions. One advantage of this arrangement is that it can provide balanced properties in two dimensions, which can be beneficial for certain device applications. For example, in ferroelectric materials, a biaxial texture can result in more uniform polarization switching behavior, improving device reliability.

It may be provided that the rock salt layer comprises a first rock salt layer formed with a fiber texture and a second rock salt layer formed above the first rock salt layer. One advantage of this arrangement is that it can combine the benefits of both fiber and biaxial textures, leading to further improvements in device performance. For example, in resistive switching materials, the combination of textures can promote the formation of more controllable and reliable conducting filaments, enhancing switching characteristics.

It may be provided that the second rock salt layer is formed of the same material as the first rock salt layer. This arrangement, known as homoepitaxy, ensures a seamless interface between the two rock salt layers, reducing interfacial defects and improving crystal quality.

It may be provided that the buffer layer inherits a texture from the rock salt layer. This arrangement ensures that the buffer layer has a similar crystallographic orientation as the rock salt layer, promoting the epitaxial growth of the functional layer with improved crystal quality and reduced strain.

It may be provided that the epitaxial functional layer inherits a texture from the buffer layer. This arrangement ensures that the functional layer has the desired crystallographic orientation, optimizing its functional properties for the specific device application.

It may be provided that the epitaxial functional layer is formed of a spintronic material. This arrangement introduces spintronic functionalities into the device, enabling applications such as magnetic sensors, non-volatile memory, and quantum computing.

It may be provided that the epitaxial functional layer is formed of a ferroelectric material. This arrangement introduces ferroelectric functionalities into the device, enabling applications such as FeRAM and piezoelectric devices.

It may be provided that the epitaxial functional layer is formed of a resistive switching material. This arrangement introduces resistive switching functionalities into the device, enabling applications such as memristors and neuromorphic computing.

It may be provided that the article has the properties of a two-terminal resistive device. One advantage of this arrangement is that it simplifies device design and fabrication, as only two electrical contacts are required for operation. This also facilitates integration with CMOS circuitry.

It may be provided that the article further comprises a second article that is formed on the same CMOS wafer and does not include a rock salt layer. This arrangement enables the fabrication of devices with multiple regions having different functionalities, allowing for more complex device designs.

It may be provided that the second article is configured to have a perpendicular magnetization orientation relative to the article that includes the rock salt layer. One advantage of this arrangement is that it can create a magnetic domain wall between the two regions, which can be used for various spintronic applications.

It may be provided that the article and the second article are configured to form a magnonic crystal device. A magnonic crystal device may be understood as a device that controls the propagation of spin waves, also known as magnons, which are collective excitations of electron spins in magnetic materials. One advantage of this arrangement is that it enables the manipulation of spin waves for information processing and communication applications.

It may be provided that the article and the second article are configured to have different resistance levels. One advantage of this arrangement is that it allows for the creation of distinct device states with different resistance values, which can be used for memory or neuromorphic computing applications.

It may be provided that a method comprises providing a CMOS wafer. This step establishes the starting point for the fabrication process, providing a suitable substrate for the subsequent growth and integration of functional materials.

It may be provided that the method comprises forming a plurality of contact electrodes on a surface of the CMOS wafer. This step creates electrical contact points that will connect the functional materials to the underlying CMOS circuitry, enabling communication and control of the device.

It may be provided that the method comprises forming a bottom electrode contact on the surface of the CMOS wafer and in electrical contact with one of the plurality of contact electrodes. This step establishes a bottom electrical contact for the device, enabling the flow of current through the functional materials and the operation of the device as a two-terminal device.

It may be provided that the method comprises forming a rock salt layer above the bottom electrode contact. One advantage of this step is that it introduces a template layer with a cubic crystal structure, which promotes the subsequent growth of epitaxial functional layers with improved crystal quality and reduced defects, leading to enhanced device performance.

It may be provided that the method comprises growing a buffer layer above the rock salt layer. One advantage of this step is that it further improves the crystal quality of the epitaxial functional layer by mitigating the lattice mismatch between the rock salt layer and the functional material. The buffer layer also enhances adhesion, improving device reliability.

It may be provided that the method comprises growing an epitaxial functional layer above the buffer layer. This step introduces the desired functionality, such as spintronics, ferroelectrics, or resistive switching, into the device. The epitaxial growth ensures that the functional layer inherits the crystal structure and orientation of the underlying layers, resulting in optimal device performance.

It may be provided that the method comprises forming a top electrode contact above the epitaxial functional layer and configured to convey electrical signals to one of the plurality of contact electrodes. This step provides a top electrical contact for the device, completing the electrical circuit and enabling the operation of the device as a two-terminal device.

It may be provided that the method comprises forming an insulating dielectric between the top electrode contact and the bottom electrode contact. One advantage of this step is that it ensures electrical isolation between the top and bottom electrodes, preventing short circuits and enabling the proper functioning of the device. This also allows for the control of the current flow through the functional material, which is essential for achieving the desired device characteristics.

It may be provided that forming the rock salt layer includes forming the rock salt layer with a fiber texture. One advantage of this step is that it can enhance the anisotropic properties of the functional materials, leading to improved performance in specific directions. For example, in spintronic devices, a fiber texture can promote spin transport along the fiber direction, reducing spin scattering and increasing spin diffusion lengths.

It may be provided that growing the buffer layer includes growing the buffer layer to inherit a texture of the rock salt layer. One advantage of this step is that it ensures that the buffer layer has a similar crystallographic orientation as the rock salt layer, promoting the epitaxial growth of the functional layer with improved crystal quality and reduced strain.

It may be provided that growing the epitaxial functional layer includes growing the epitaxial functional layer to inherit a texture of the buffer layer. This step ensures that the functional layer has the desired crystallographic orientation, optimizing its functional properties for the specific device application.

It may be provided that the method further comprises forming a second article that does not include a rock salt layer on the same CMOS wafer as the article. One advantage of this step is that it enables the fabrication of devices with multiple regions having different functionalities, allowing for more complex device designs and expanding the range of potential applications.

### BRIEF DESCRIPTION OF THE DRAWINGS

The patent or application file contains at least one drawing executed in color. Copies of this patent or patent application publication with color drawings will be provided by the Office upon request and payment of the necessary fee.

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows an epitaxially-grown memory device 200, according to some embodiments.

FIG. 2 shows, according to some embodiments, an epitaxially-grown memory device 200.

FIG. 3 shows, according to some embodiments, an epitaxially-grown memory device 200.

FIG. 4 shows, according to some embodiments: (a) magnesium oxide (MgO) undergoes a thermodynamically favorable transition from spherical grains into cubic <100> crystallites on a flat, chemically non-interacting surface. Under this scenario crystallites form in a fiber texture, with no preferential texturing within the plane of the growth. (b) Due to channeling of the <110> directions, a 45 degree Ar⁺ ion beam preferentially textures the crystal within the plane. (c) The difference between fiber texture and biaxial texture side view and (d) top view.

FIG. 5 shows, according to some embodiments, a process for making an epitaxially-grown memory device 200.

FIG. 6 shows, according to some embodiments, a process for selective area deposition of a rock salt layer using a shadow mask above a CMOS wafer.

FIG. 7 shows, according to some embodiments, a process for selective area deposition of a rock salt layer using a lift-off technique with a resist-coated CMOS Wafer.

FIG. 8 shows, according to some embodiments, a process for selective area deposition of a rock salt layer using a subtractive technique with a resist-coated rock salt layer on a CMOS Wafer.

FIG. 9 shows, according to some embodiments, a selective area epitaxial layer on a CMOS wafer coated with lithographically-defined rock salt islands showing magnetic domains alternating between film-normal and in-plane directions as a magnonic crystal.

FIG. 10 shows, according to some embodiments, texture in rock salt thin films, with (a) polycrystalline texture; (b) fiber texture and (c) biaxial texture.

FIG. 11 shows, according to some embodiments, a cross-section of spontaneous relaxation of spherical rock salt crystallites on CMOS Wafer transforming into <100> fiber textured crystallites taking a rectangular solid shape. Large and small spheres represent the two distinct atoms showing a checkerboard-type pattern within the rock salt chemical compound.

FIG. 12 shows, according to some embodiments, (a) an oblique view of (top) fiber texture and (bottom) biaxial texture; (b) top view of (left) fiber texture and (right) biaxial texture. Figures serve to highlight the flat, mutually (001) textured surfaces for both fiber and biaxially textured films, with the primary difference in the mutual coordination of the rectangular crystallite boundaries within the plane of biaxially textured films, giving a nearly single-crystalline texture to be received by overlaid epitaxial functional layers.

FIG. 13 shows, according to some embodiments, ion beam assisted deposition of a rock salt layer onto a CMOS substrate. A physical vapor deposition source (thermal or electron beam evaporation, or direct current or radio frequency magnetron sputtering, or ion beam sputtering) forms a layer of a rock salt thin film on the CMOS substrate. Simultaneous bombardment from the ion assist beam oblique to the CMOS substrate surface preferentially etches arriving crystallites of the rock salt thin film whose facets are misaligned from the biaxial texturing direction.

FIG. 14 shows, according to some embodiments, x-ray diffraction data showing the degree of alignment of the (002) facets normal to the plane of a Cr buffer layer 205 grown above an MgO(001) bulks substrate; an MgO rock salt layer 204 with biaxial texture; and a polycrystalline MgO rock salt layer 204 with no preferred texture highlighting that the degree of out-of-plane texture in Cr depends on the presence of texture in the underlying rock salt layer. The breadth (Δω) of the intensity peak in degrees ω corresponds to the spread of (002) facets tilting away from the out-of-plane direction.

FIG. 15 shows, according to some embodiments, x-ray diffraction data showing the degree of alignment of the (200) facets within the plane of a Cr buffer layer 205 grown above an MgO(001) bulks substrate; an MgO rock salt layer 204 with biaxial texture; and a polycrystalline MgO rock salt layer 204 with no preferred texture highlighting that the degree of in-plane texture in Cr depends on the presence of texture in the underlying rock salt layer. The breadth (Δφ) of the intensity peak in degrees φ corresponds to the spread of (200) facets away from the four-fold symmetry axis. In both polycrystalline MgO and FIBER-textured MgO films, there is no biaxial texturing to serve as a template for the Cr film and consequently the film will have (200) facets that reflect at all azimuthal angles φ within the plane of the sample.

### DETAILED DESCRIPTION

A detailed description of one or more embodiments is presented herein by way of exemplification and not limitation.

Carefully engineered crystalline materials have been driving the exponential growth in electronic and optical technologies for decades. For example, in complementary metal oxide semiconductor (CMOS) circuitry, the transistors are fabricated on ultra-pure mono-crystalline Silicon bulks (wafers) as needed for a high mobility channel. Single-crystalline thin films can be deposited by epitaxy on single-crystalline bulks; however, they require carefully matched lattices and elevated temperatures for deposition. This makes monolithic integration of new devices on top of CMOS a challenge since it limits the choice of materials and the underlying transistor circuitry cannot withstand the deposition temperature of epitaxial films. Therefore, the majority of the films utilized in add-on devices on CMOS are amorphous or polycrystalline with small grain sizes.

The existing technology makes monolithic integration of new devices on top of CMOS a challenge since it limits the choice of materials and the underlying transistor circuitry cannot withstand the deposition temperature of epitaxial films. Therefore, the majority of the current films utilized in add-on devices on CMOS have less than ideal properties, due to the fact that they are amorphous or polycrystalline with small grain sizes.

These films will be used for growing stacks of high-quality thin films of use in a variety of applications. One example of such a device is the resistive switching (or memristor) device, which has a two-terminal design with a layer (or stack) of oxide(s) sandwiched between two electrodes. In another similar embodiment, the device is the magnetic switching or (magnetic tunnel junction) device, which also has a two-terminal design with a series of ferromagnetic layers with an insulating oxide separating one pair of ferromagnets, all of which are similarly sandwiched between two electrodes. Using the biaxial-MgO films, the entire stack may be deposited all at once. An ultra-smooth bottom electrode material, the barrier (e.g. biaxial-MgO), active film(s) and top electrode films will be deposited in the same sputtering step, following by patterning, and controlled ion milling.

It has been discovered that a novel methodology and class of materials and devices are complementary metal-oxide semiconductor (CMOS) compatible based on buffer materials, such as MgO <100> that crystallizes at suitably low temperatures even on amorphous substrates. Under the influence of a beam of charged particles (e.g., Ar⁺) directed obliquely to the CMOS substrate surface, an MgO film growing above that surface will have its constituent crystallites aligned in the direction of the beam. These buffer MgO crystallite films will be used for growing stacks of high-quality thin films of use in a variety of applications. One example of such a device is the resistive switching (or memristor) device, and another is the magnetic tunnel junction (MTJ) device, both which could be made of high-quality active films thanks to this methodology.

A method for forming epitaxially-grown thin films and devices monolithically on semiconductor chips involves insertion of a thin (<10 nm) magnesium oxide buffer layer film that develops biaxial (within the film plane and perpendicular to the film thickness) orientation (biaxial-MgO) of constituent crystallites under the influence of energetic ion beam bombardment during the initial stages of its growth. The growth of the thin biaxial-MgO layer can be carried out at semiconductor compatible low temperatures as can the epitaxially-grown thin films. This method expands a previously restricted material space of polycrystalline or untextured materials to include many technologically advantageous epitaxial films, including high-entropy oxides, ferroelectric relaxors, topological semimetals and magnetic tunnel junctions.

As maturation is underway of non-Si based CMOS chips with larger band gaps, higher operating and consequently processing temperatures for memory devices disposed on wide bandgap CMOS chips may provide opportunity for growth and utility of technologically advantageous epitaxial films, including high-entropy oxides, ferroelectric relaxors, topological semimetals, and magnetic tunnel junctions.

It should be recognized that conventional methods for integrating functional materials with CMOS technology often suffer from challenges related to lattice mismatch, thermal expansion coefficient mismatch, and interfacial defects. These issues can lead to poor crystal quality, degraded device performance, and reduced reliability. The epitaxially-grown memory device 200 described herein overcomes these limitations associated with conventional approaches. It has been discovered that epitaxially-grown memory device 200 that includes a CMOS wafer, contact electrodes, a bottom electrode contact, a rock salt layer, a buffer layer, an epitaxial functional layer, a top electrode contact, and an insulating dielectric provides a novel and effective solution for integrating functional materials with CMOS technology.

One advantage of epitaxially-grown memory device 200 is that it enables the epitaxial growth of functional materials with improved crystal quality and reduced defects. The rock salt layer, with its cubic crystal structure, serves as a template for the subsequent growth of the epitaxial functional layer, promoting crystallographic alignment and minimizing strain. This leads to enhanced device performance, such as higher tunneling magnetoresistance in spintronic devices, higher polarization and more reliable switching behavior in ferroelectric devices, and more controllable and reliable resistive switching characteristics in memristive devices.

The buffer layer plays a role in further improving crystal quality by mitigating the lattice mismatch between the rock salt layer and the functional material. This reduces interfacial defects and enhances the overall structural integrity of the device.

The insulating dielectric ensures electrical isolation between the top and bottom electrode contacts, preventing short circuits and enabling the proper functioning of the device as a two-terminal device. This allows for precise control of the current flow through the functional material, which is essential for achieving the desired device behavior and performance.

Herein is described buffer layer materials that preferentially crystallize at low CMOS-compatible temperatures, even when deposited on amorphous or polycrystalline substrates. Rock salt materials, a class of ionic solids with a two atom basis, constitute an advantageous subset of materials for this purpose, due to their preference to grow with their <100> facets oriented normal to their growth direction. We recognized the possibility to grow high quality, e.g. biaxially-textured, rock salt (biaxial-RS) films on ultra-smooth bottom electrode material, or directly on the gate dielectric material between metallized vias at the surface of CMOS wafers. In order to be CMOS compatible, these biaxial-RS films and subsequent films have to be deposited or annealed at low temperatures. This is made possible due to the advantageous material property called channeling, which manifests itself in a substantially higher tolerance to ion bombardment of the <101> facets of the RS crystal lattice. Indeed, under the influence of a beam of charged noble gas ion particles directed obliquely to the CMOS substrate surface, an RS film growing above that surface will have its constituent crystallites aligned in the direction of the beam. In certain embodiments, the constituent crystallites will align with very narrow misorientation within the plane of the growing film and out of the plane of the growing film. In other embodiments, the crystallites will align with very narrow misorientation out of the plane of the growing film but with a continuous distribution of orientations within the plane of the growing film (e.g. the crystallites will not texture within the plane of the growing film).

The flexibility of the technique of inserting textured RS films into CMOS wafer processing presents several advantages. First, it enables exploration of epitaxial film materials on large-scale semiconductor wafers at the prototype stage whereas previously the restriction of using only single-crystalline bulks has restricted use typically to 75 mm diameter wafers or smaller. Second, the RS film can be inserted as a back-end-of-line compatible, epitaxial replacement of the gate dielectric layer or bottom electrode replacement, depending on the choice of RS, with several conductors and insulators within the subset of RS materials. Third, the RS layer can enable the integration of monolithic epitaxial functional devices in a type of three-dimensional memory architecture called cross-point, in which functional devices are placed at the intersection between horizontal and vertical laminations of word lines and bit lines, with a selector layer enabling the three-dimensional routing of signals to individual devices. The RS layer can be repeated each time a new plane of functional devices is grown above a bit-line or word line interlayer, restoring the epitaxial template for monolithic growth of the epitaxial functional device array.

The article described herein provides heterogeneous integration of crystalline thin film functional devices with CMOS circuitry for computer memory and logic applications. Materials comprising a multitude of mutually-aligned crystallites deliver performance gains over their amorphous and polycrystalline counterparts, particularly in relevant metrics for microsystems, including read-and-write energy, read-and-write speed, endurance, non-volatility, scalability, etc. Crystalline thin film functional devices require an epitaxially matched lattice to induce the coherent growth of thin films whose constituent grains develop a crystalline registry with the underlying matched lattice. This article includes a rock-salt layer (RS) disposed directly below a series of epitaxial functional layers. The RS layer is composed of a multitude of crystallites with a smooth top surface that serves to set the alignment of the crystallites of the overlaid epitaxial functional device. Depending on whether the RS is fiber-textured or biaxially-textured, the epitaxial functional device will similarly inherit a fiber-texture or biaxial-texture.

A process described herein provides for forming an epitaxially-grown device on a CMOS substrate whose surface is otherwise incompatible with epitaxially-grown devices, an impediment to realizing the advantageous performance of heterogeneously integrated epitaxial devices on CMOS, whose faster read and write speeds, lower read and write energies and other advantageous properties like homogeneity, reproducibility, fatigue cycling and non-volatility convey significant improvements over polycrystalline or amorphous material counterparts that can be readily integrated on CMOS without any modifications. We have developed an article that inserts above the CMOS substrate a thin film alloy—with rock salt structure—whose ability under specialized processing conditions to exemplify coherent crystalline texture delivers substantial epitaxial influence on the layers that follow in near perfect analogy with the bulk single-crystalline substrate that the rock salt film seeks to mimic. The process of forming the layers on a CMOS substrate in such a way as to create a fully-functional nanoelectronic device will be described below.

In an embodiment, epitaxially-grown memory device 200 includes: a CMOS wafer; a plurality of contact electrodes making electrical contact to metallized VIAs and disposed at a surface of the CMOS wafer; a bottom electrode contact making electrical contact to one of the plurality of contact electrodes and also disposed at the surface of the CMOS wafer; a rock salt layer formed above the bottom electrode; a buffer layer grown above the rock salt layer; an epitaxial functional layer grown above the buffer layer; a top electrode contact grown above the epitaxial functional layer and configured to convey electrical signals to one of the plurality of contact electrodes; and an insulating dielectric formed between the top electrode contact and the bottom electrode contact. In an embodiment, the rock salt layer is formed with a fiber texture. In an embodiment, the rock salt layer is formed with a biaxial texture. In an embodiment, the rock salt layer includes a first rock salt layer formed with a fiber texture and a second rock salt layer formed above the first rock salt layer. In an embodiment, the second rock salt layer is formed of the same material as the first rock salt layer. In an embodiment, the buffer layer inherits a texture from the rock salt layer. In an embodiment, the epitaxial functional layer inherits a texture from the buffer layer. In an embodiment, the epitaxial functional layer is formed of a spintronic material. In an embodiment, the epitaxial functional layer is formed of a ferroelectric material. In an embodiment, the epitaxial functional layer is formed of a resistive switching material. In an embodiment, the article has the properties of a two-terminal resistive device. In an embodiment, epitaxially-grown memory device 200 includes a second epitaxially-grown memory device 200 that is formed on the same CMOS wafer and does not include a rock salt layer. In an embodiment, the second epitaxially-grown memory device 200 is configured to have a perpendicular magnetization orientation relative to the article that includes the rock salt layer. In an embodiment, the epitaxially-grown memory device 200 and the second epitaxially-grown memory device 200 are configured to form a magnonic crystal device. In an embodiment, the epitaxially-grown memory device 200 and the second epitaxially-grown memory device 200 are configured to have different resistance levels.

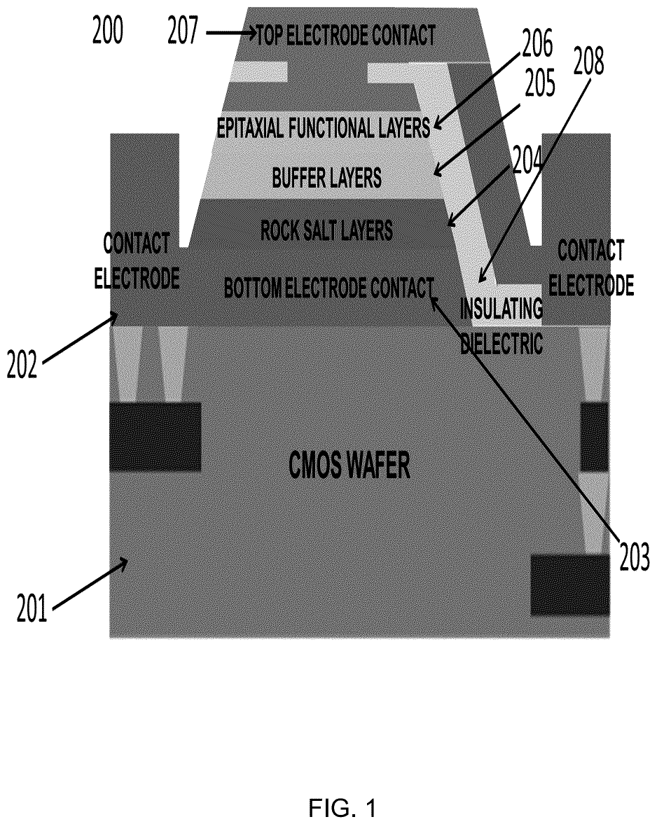

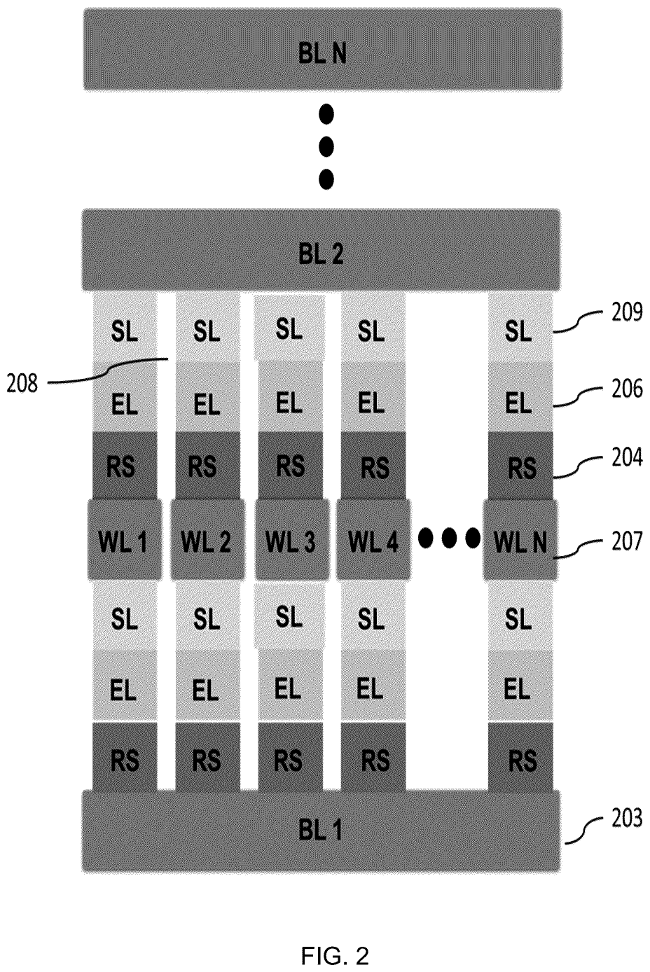

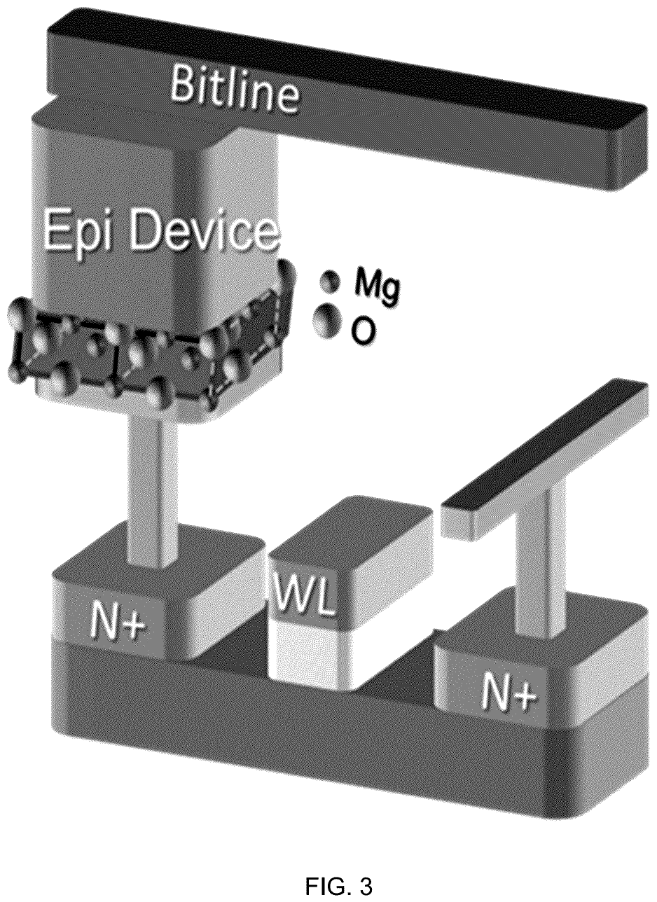

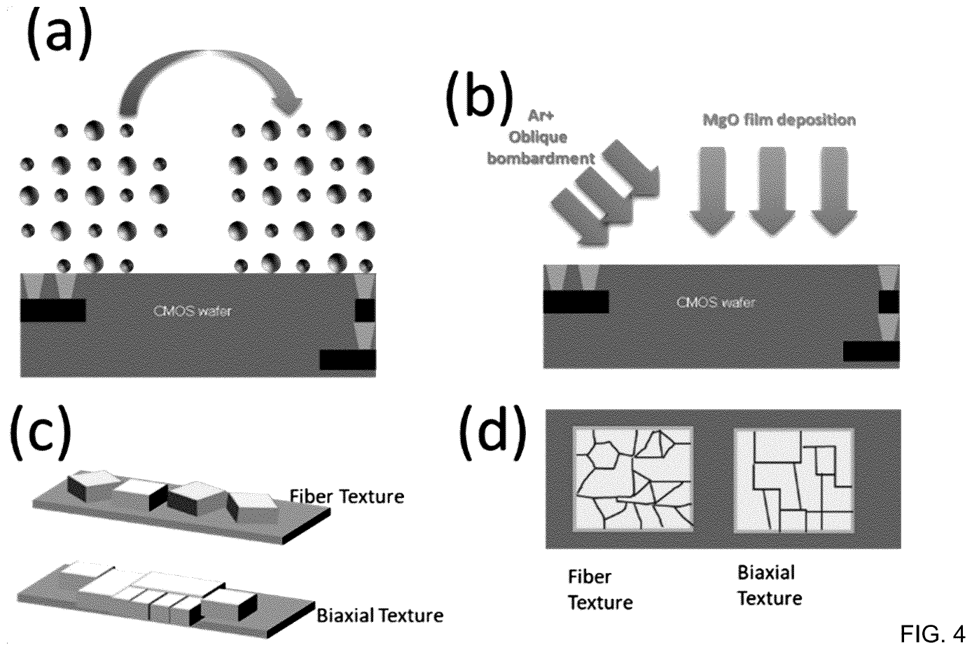

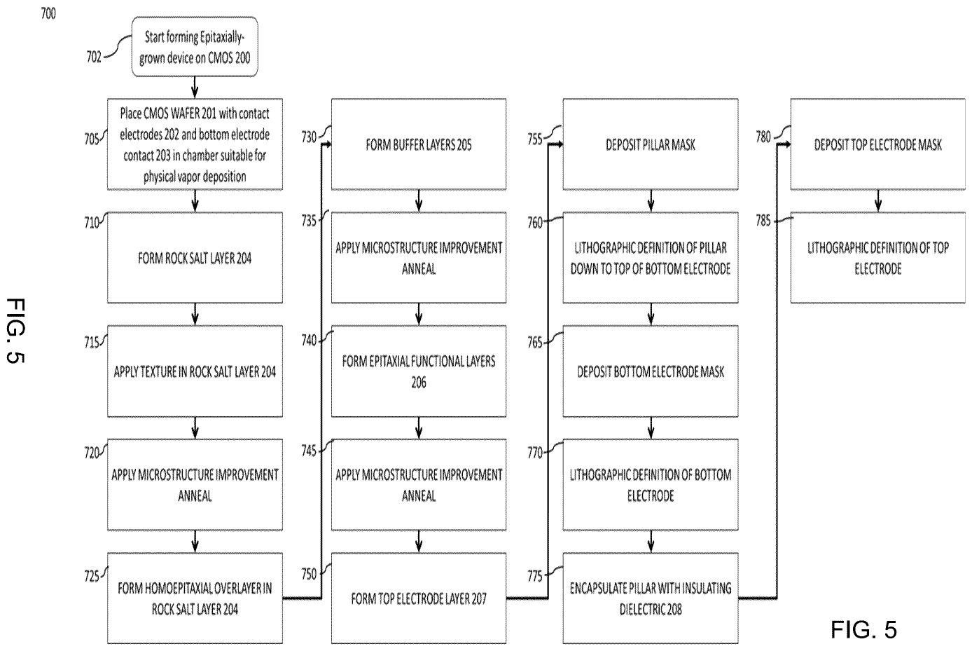

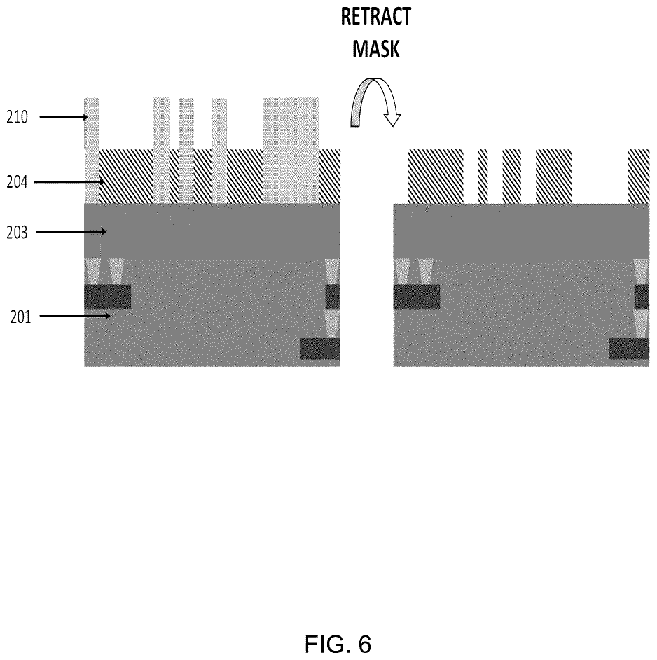

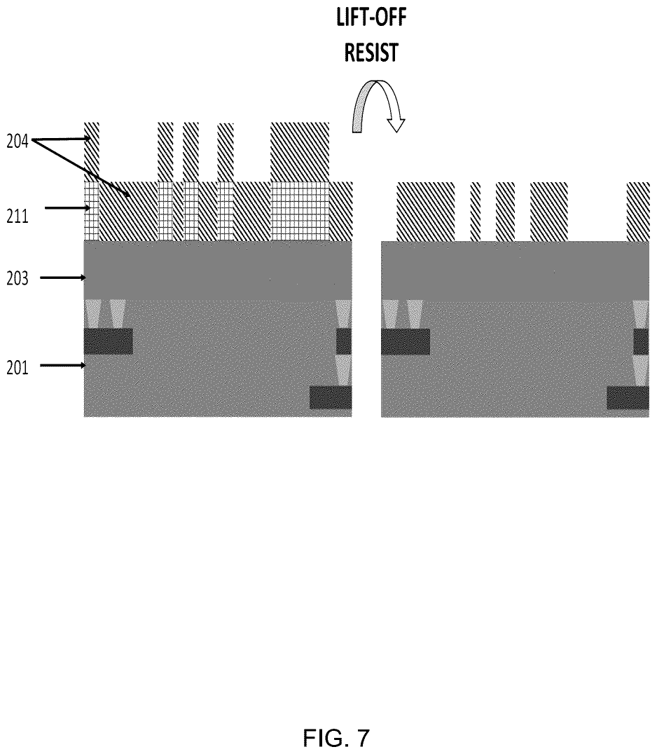

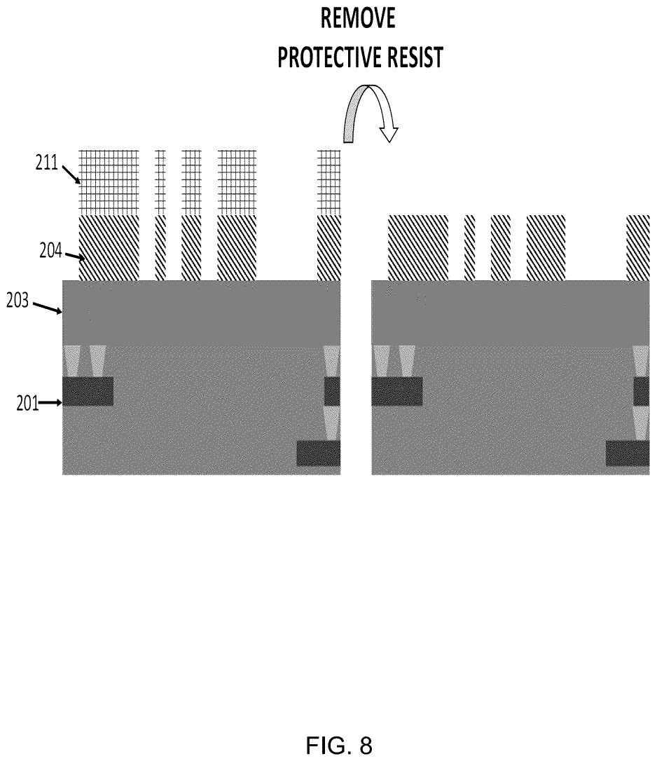

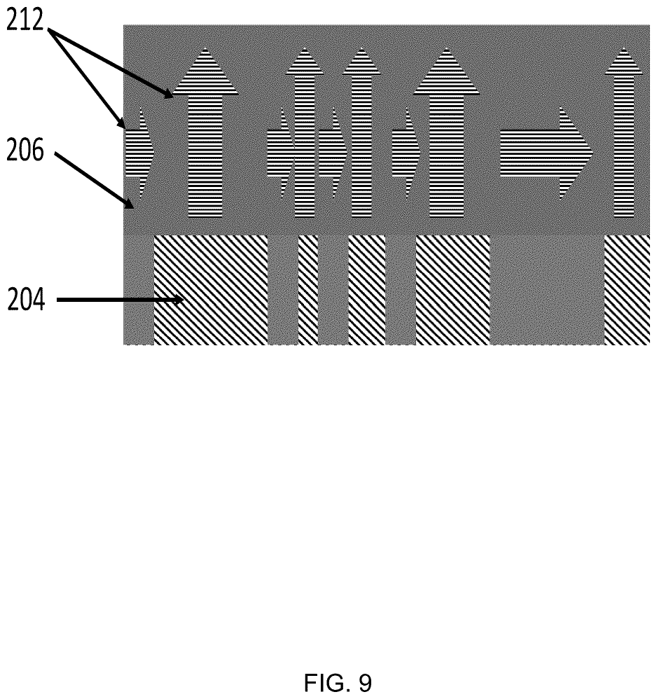

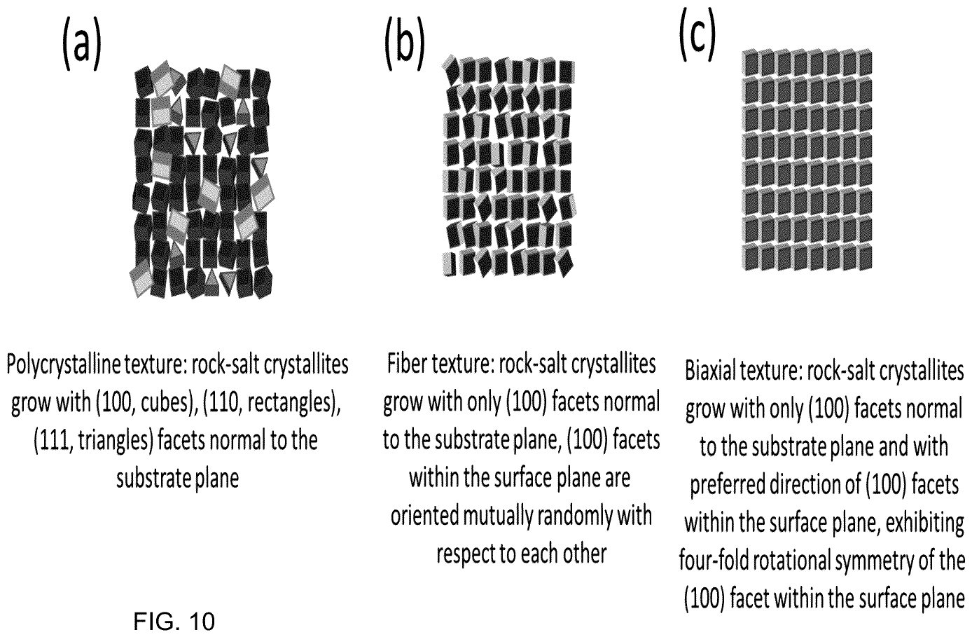

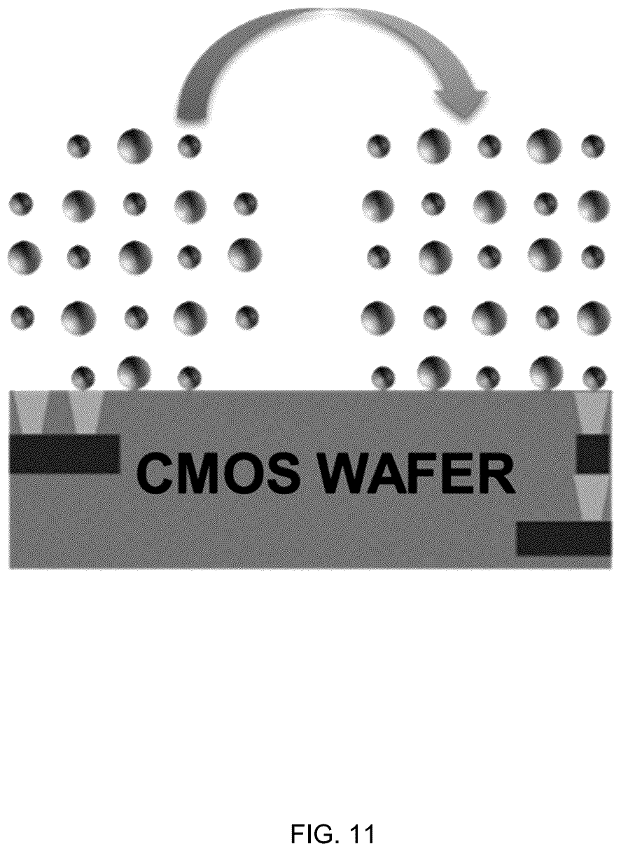

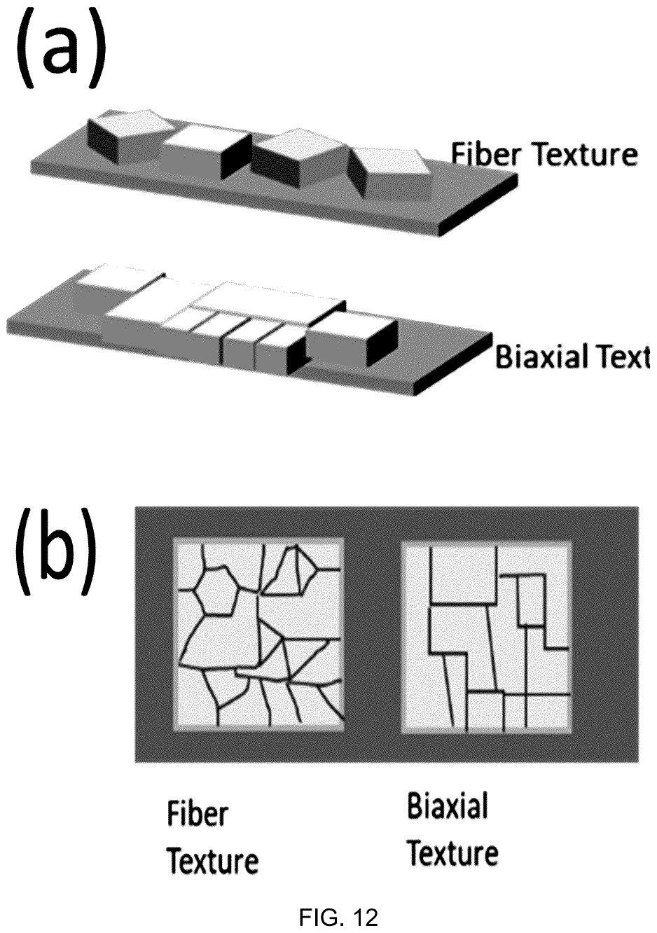

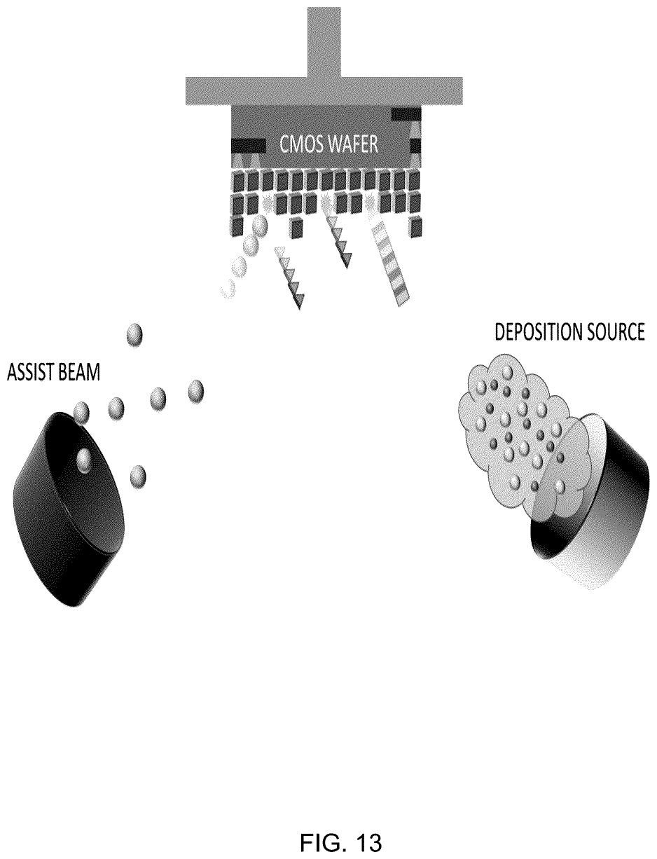

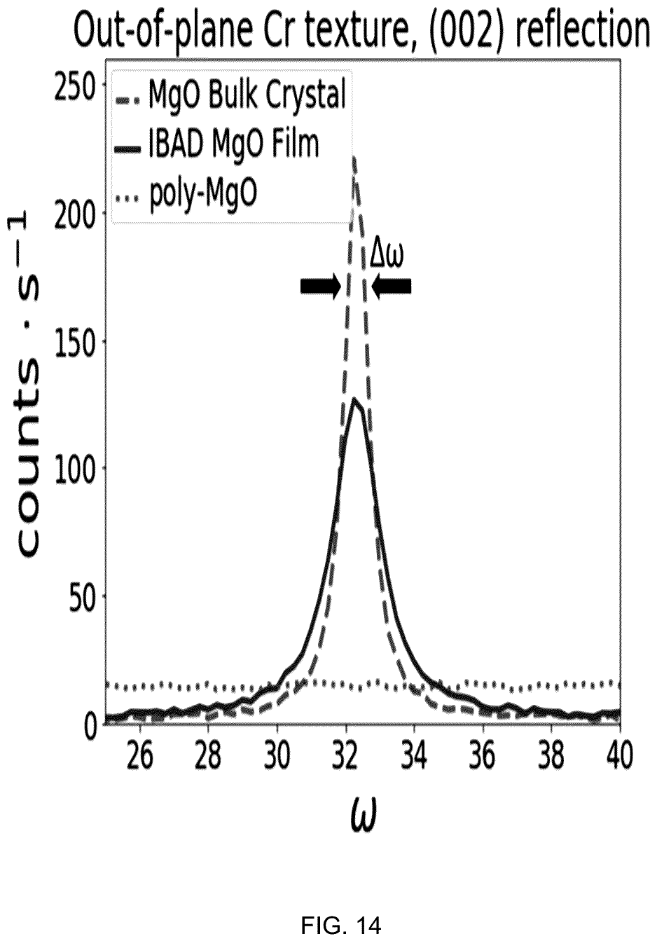

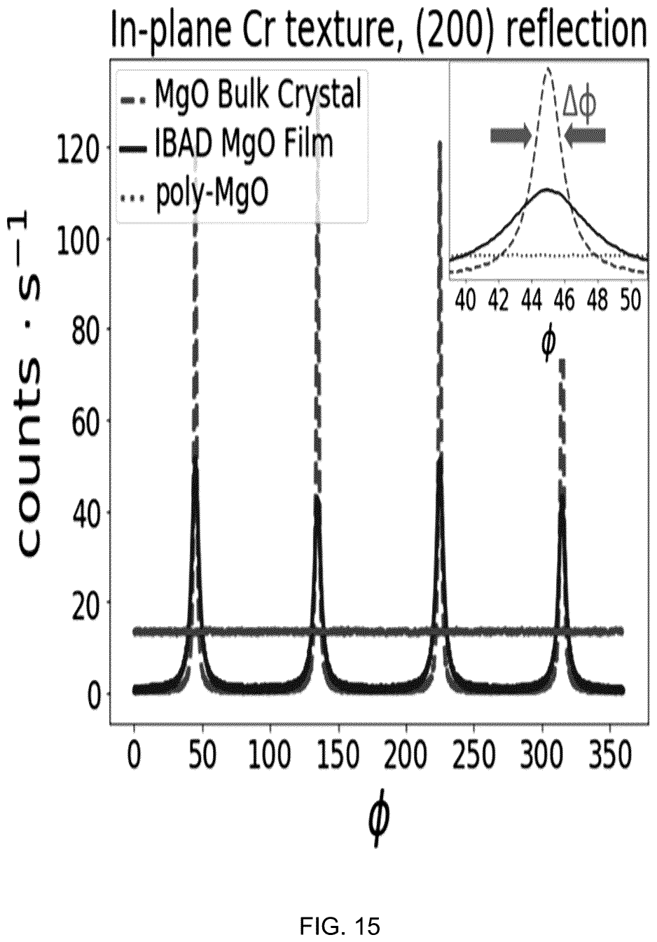

In an embodiment, with reference to FIG. 1, FIG. 2, FIG. 3, FIG. 4, FIG. 5, FIG. 6, FIG. 7, FIG. 8, FIG. 9, FIG. 10, FIG. 11, FIG. 12, FIG. 13, FIG. 14 and FIG. 15, epitaxially-grown memory device 200 includes: a CMOS wafer 201; contact electrodes 202 making electrical contact to metallized VIAs and disposed at the surface of CMOS wafer 201; bottom electrode contact 203 making electrical contact to one of the Contact electrodes 202 and also disposed at the surface of the CMOS wafer 201; rock salt layers 204 that can include a single rock salt layer that is formed with a fiber texture or a biaxial texture or a combination of a single rock salt layer that is formed with a fiber texture or a biaxial texture with an overlaid rock salt layer of the same material (referred to as a homoepitaxial rock salt layer) that inherits its texture, either fiber or biaxial, from the underlying rock salt layer; buffer layers 205 that are grown above the rock salt layers 204 and inherit their texture, either fiber or biaxial, from the underlying rock salt layers 204, and serve as both an advantageous adhesion layer to the rock salt layers 204 and as bridge layers to bridge the mismatch between the crystal lattice spacing of the rock salt layers 204 and subsequent layers in the epitaxially-grown devices on CMOS 200; epitaxial functional layers 206 that are grown above the buffer layers 205 and inherit their texture, either fiber or biaxial, from the underlying buffer layers 205; top electrode contact 207 that is grown above the epitaxial functional layers 207 and communicates electrical signals to one of the contact electrodes 202; and insulating dielectric 208 that is formed between the top contact electrode and the layers 203-206 to ensure electrical isolation between the top electrode and bottom electrode, which in turn enables the operation of epitaxially-grown device on CMOS 200 as a two-terminal device, where electrical signals are routed in the direction perpendicular to the interfaces between the layers of this device, between the top electrode contact 207 and the bottom electrode contact 203.

The article 200 has the properties of a two-terminal resistive device integrated with semiconductor CMOS electrodes for electrical stimulation. The properties of the resistive device depend largely on the epitaxial functional layers 206. Epitaxial functional layers 206 can take the form of spintronic materials, ferroelectric materials, or resistive switching materials. The epitaxial texture will result in improved performance of the functional layers, which for spintronic/topological materials could manifest in higher tunneling magnetoresistance, higher non-volatile storage times for smaller size memory devices, and lower high-frequency losses; for ferroelectric materials it could manifest in higher polarization, more reliable polarization switching behavior, less fatigue/failure characteristics, non-destructive read, and better reliability at smaller device size; for resistive materials it could manifest in more controllable formation and annihilation of conducting filaments, coherent Mott transitions and more reliable switching behavior. The epitaxial functional layers 206 are derived from a class of materials, including cubic or pseudo-cubic spintronic/topological materials (X_{2}YZ and X_{3}Z Heusler alloys and L1_{0}-phase intermetallics to name a few), tetragonal complex oxides for ferroelectric materials, and Mott insulators and high entropy oxides for resistive materials.

The article 200 also consists of devices based on patterned rock salt layers 204, whereby a single device has regions coated with rock salt layer 204 and complementary regions without rock salt layer 204. Epitaxial functional layer 206 will inherit biaxial or fiber texture only in regions including rock salt layer 204, leading to selective-area epitaxy within a single device. Devices formed from the selective deposition of textured and untextured epitaxial functional layer inherit (at least) two controlled regions 212 with a transition between the two regions included. For spintronic/topological materials, area-selective modification of the magnetization orientation is desirable to form a magnonic crystal for controlled transmission of information encoded in magnetic spin wave (or magnon) excitations. In engineered regions of textured functional layer, a perpendicular magnetization orientation to adjacent regions of untextured functional layer is formed, generating the formation of a magnonic crystal device. For ferroelectric/resistive materials, area-selective control of the ferroelectric or resistive properties could be engineered to realize distinct device resistance levels for memristive memory elements or neuromorphic synaptic (resistive) weights.

The specific implementation of each element in the epitaxially-grown memory device 200 contributes to several technical advantages. The use of a CMOS wafer provides a foundation for integration with established semiconductor technology. The contact electrodes and bottom electrode contact facilitate electrical connections and enable the flow of current. The rock salt layer promotes epitaxial growth and improves crystal quality. The buffer layer further enhances crystal quality and adhesion. The epitaxial functional layer introduces the desired functionality. The top electrode contact completes the electrical circuit, and the insulating dielectric ensures electrical isolation and proper device operation.

The epitaxially-grown memory device 200 includes a CMOS wafer 201, which serves as the foundation for the device. The CMOS wafer can be fabricated from various semiconductor materials, including silicon (Si), germanium (Ge), gallium arsenide (GaAs), silicon carbide (SiC), gallium nitride (GaN), gallium oxide (Ga2O3), and heterogeneous metal-oxide-semiconductor (MOS) structures. The choice of semiconductor material depends on the specific requirements of the device and the desired functionality. The CMOS wafer incorporates a multitude of lithographically defined transistors, metallized VIAs, and gate dielectric, providing the necessary circuitry for logic and memory control functions. It is contemplated that CMOS wafer 201 is a wafer of semiconductor material, which can be a CMOS wafer that is doped silicon, wide bandgap (WBG) semiconductor (e.g., possessing a lager bandgap at room temperature than conventional bulk Si CMOS circuits or approximately 1.1 electron-Volts, e.g., SiC, Al—Ga—N alloys, BN, Diamond, Ga2O3, GeO2, SnO2, and certain ternary oxides like ZnGa2O4 and MgGa2O4. . . ), multilayers of CMOS and/or WBG semiconductors, or alternating islands of CMOS and WBG, or alternating islands of two or more WBG semiconductors on a heterogeneous substrate. In an embodiment, the substrate possesses a multitude of lithographically defined transistors, metallized VIAs and gate dielectric for the purpose of transistor-based electronic signal routing for fundamental logic and memory control circuitry. In an embodiment, CMOS wafer 201 is a semiconductor logic chip with a plurality of transistors dipsosed on the semiconductor logic chip, wherein the semiconductor logic chip includes various semiconductor materials, including Si, Ge, Ga, and the like, such that CMOS wafer 201 is SiC, SiGe, GaAs, GaN, Ga₂O₃, or heterogeneous MOS with one p-channel element and an n-channel element

The epitaxially-grown memory device 200 includes a plurality of contact electrodes 202 that are responsible for routing electrical signals from the substrate to the functional device formed during back-end-of-line processing. These contact electrodes can be formed from various electrically conductive materials, such as copper (Cu), ruthenium (Ru), tungsten (W), tantalum (Ta), cobalt (Co), and their alloys, such as titanium nitride (TiN), tantalum nitride (TaN), molybdenum phosphide (MoP), cobalt silicide (CoSi), niobium arsenide (NbAs), tantalum arsenide (TaAs), and cobalt tin (CoSn). The choice of material for the contact electrodes is determined by factors such as electrical conductivity, adhesion, and compatibility with the CMOS fabrication process. In an embodiment, contact electrodes 202 route electrical signals from the substrate to a device formed during back-end-of-line processing. In an embodiment, contact electrodes 202 are formed from various electrically conducting elemental materials, including Cu, Ru, W, Ta, Co, and the like, or from electrically conducting alloys, including TiN, TaN, MoP, CoSi, NbAs, TaAs, CoSn and the like. These elemental materials may have an amorphous crystalline structure or may have nanocrystalline texture, with individual grain sizes determined by the processing used in their synthesis. Processing kits specified by the semiconductor foundry (Fab) that produces the CMOS wafer 201 and/or carries out the subsequent back-end-of-line addition of metallization contacts, and integration of discrete/standalone and embedded memory and logic devices will specify the exact types of materials that can be accepted into their fab for contact electrodes 202.

A bottom electrode contact 203 is formed as a back-end-of-line component to make contact with one of the contact electrodes 202. Similar to the contact electrodes, the bottom electrode contact can be formed from various electrically conducting materials, including elemental metals and alloys. The specific material choice depends on factors such as electrical conductivity, adhesion to the underlying rock salt layer, and compatibility with the fabrication process. In an embodiment, bottom electrode contact 203 is formed as a back-end-of-line component to contact one of the contact electrodes 202 and are formed from various electrically conducting elemental materials, including Cu, Ru, W, Ta, Co, and the like, or from electrically conducting alloys, including TiN, TaN, MoP, CoSi, NbAs, TaAs, CoSn, CrNi, CrRu, CuN, and the like and multilayers composed of the above mentioned materials or alloys. These elemental materials may have an amorphous crystalline structure or may have nanocrystalline texture, with individual grain sizes determined by the processing used in their synthesis, which could include: electron-beam or thermal evaporation, ion-beam or magnetron direct current or radio frequency sputtering.

A rock salt layer 204 is formed above the bottom electrode contact 203 and is engineered to possess either a fiber texture or a biaxial texture. Rock salt layers are typically composed of insulating or conducting metal oxides or nitrides, such as titanium oxide (TiO), vanadium oxide (VO), magnesium oxide (MgO), manganese oxide (MnO), nickel oxide (NiO), cobalt oxide (CoO), zinc oxide (ZnO), titanium nitride (TiN), tantalum nitride (TaN), zirconium nitride (ZrN), hafnium nitride (HfN), vanadium nitride (VN), and tungsten nitride (WN). The choice of material for the rock salt layer depends on factors such as lattice constant matching with the epitaxial functional layer, desired electrical properties, and compatibility with the deposition process. In embodiment, rock salt layers 204 are formed above the bottom electrode contact 203 and are engineered to possess either fiber texture or biaxial texture. Rock salt layers are a thin film complex that includes an assembly of small crystallites that are oriented with either: a single preferred facet orientation perpendicular to the film plane with random in-plane orientation, or fiber texture; or a single preferred facet orientation perpendicular to the film plane and a single preferred facet orientation within the film plane of the layers, or biaxial texture. The size of the individual constituent crystallites scales in proportion with the thickness of rock salt layers 204. Rock salt layers could be composed of an insulating alloy, including TiO, VO, MgO, MnO, NiO, CoO, ZnO and several combinations thereof. It could alternatively be derived from several conducting species, including TiN, TaN, ZrN, HfN, VN and WN, The varying chemical composition leads to variation in the underlying lattice constant from below 0.42 nm to in excess of 0.45 nm, which can be advantageous in lattice matching directly with epitaxial functional layers 206 or indirectly through buffer layers 205. Rock salt layers are grown using physical vapor deposition techniques, including electron-beam or thermal evaporation, ion-beam or magnetron direct current or radio frequency sputtering and derive a fiber texture due to surface energy minimization of <100> oriented facets during thin film growth. Additional energy can be delivered during the growth of a biaxial rock salt layer through use of a noble gas ion beam directed at the preferred <101> direction of the film during growth. The channeling effect in face-centered-cubic rock salt crystals along the <101> direction preferentially etches away misaligned crystallites, leaving behind only crystallites whose (101) facets are oriented in the direction of the ion beam, and leading to the biaxial texture of the rock salt film. An additional homoepitaxial rock salt layer may be subsequently grown using physical vapor deposition techniques without the ion bombardment to manipulate residual stresses in the film and the crystallite size of the rock salt layer, for which thicker films support larger crystallite sizes on average.

Buffer layers 205 are formed above the rock salt layer 204 and serve as intermediary layers to improve adhesion and bridge the lattice constant mismatch between the rock salt layer and the epitaxial functional layer 206. Buffer layers are typically composed of conducting materials, such as titanium (Ti), tantalum (Ta), chromium (Cr), tungsten (W), and their alloys, including chromium ruthenium (CrRu), chromium titanium (CrTi), chromium tungsten (CrW), nickel chromium (NiCr), titanium nitride (TiN), and tantalum nitride (TaN). In some cases, a bilayer buffer structure may be employed, with a lower layer having good adhesion properties and an upper layer composed of a platinum-group element (Pt, Ir, Ru, Rh, Pd, Os) to address specific lattice matching requirements. In an embodiment, buffer layers 205 are formed above the rock salt layers 204 and serve as materials with advantageous adhesion properties to the rock salt layers 204 and to bridge the lattice constant mismatch between the rock salt layers 204 and the epitaxial functional layers 206. Buffer layers 205 are derived from conducting species, including Ti, Ta, Cr, W and alloys including CrRu, CrTi, CrW, NiCr, TiN, TaN and the like. In certain embodiments, materials with poor adhesion properties to the rock salt layers are needed to bridge the lattice constant mismatch between the rock salt layers 204, above mentioned buffer layers 205, and the epitaxial functional layers 206. This is particularly the case for Pt-group elements Pt, Ir, Ru, Rh, Pd, Os. In this case, buffer layers 205 can be a bilayer complex, with lower layer taken from the list of materials above with good adhesion properties, and upper layer taken from the list of Pt-group elements.

Epitaxial functional layers 206 are formed above the buffer layers 205 and provide the desired functionality of the device, whether it is a logic device or a memory device. The specific composition and structure of the epitaxial functional layers depend on the intended application. For spintronic or topological devices, the layers may include two or more epitaxial ferromagnetic electrode layers separated by an epitaxial tunnel barrier. For ferroelectric devices, the layers typically include an epitaxial ferroelectric layer sandwiched between epitaxial or polycrystalline metal contact electrodes. For resistive devices, the layers may include an epitaxial Mott insulator or an epitaxial filamentary insulator with epitaxial or polycrystalline metal contact electrodes. In an embodiment, epitaxial functional layers 206 are formed above the buffer layers 205 and deliver the desired functionality of the integral device, whether a logic device or a memory device, to be integrated with CMOS circuitry as part of epitaxially-grown memory device 200. As a spintronic or topological device, epitaxial functional layers could include at least two epitaxial ferromagnetic electrode layers with an epitaxial tunnel barrier separating the ferromagnetic layers. As a ferroelectric device, epitaxial functional layers should include the epitaxial ferroelectric layer and either epitaxial or polycrystalline metal contact electrodes on either side of the ferroelectric layer. As a resistive device, epitaxial functional layers should include an epitaxial Mott insulator or an epitaxial filamentary insulator with either epitaxial or polycrystalline metal contact electrodes on either side of the epitaxial Mott or filamentary insulator layers. Depending on the nature of the epitaxial functional layers, compatible physical vapor deposition techniques can be employed for their growth, including: electron beam or thermal evaporation; direct current or radio frequency ion beam or magnetron sputter deposition; pulsed laser deposition or molecular beam epitaxy.

A top electrode contact 207 is formed above the epitaxial functional layers 206 to contact with one of the contact electrodes 202. Similar to the bottom electrode contact, the top electrode contact can be formed from various electrically conducting materials, including elemental metals and alloys. In an embodiment, top electrode contact 207 is formed above epitaxial functional layers 206 to make contact to one of the contact electrodes 202 and can be formed from various electrically conducting elemental materials, including Cu, Ru, W, Ta, Ti, and the like, or from electrically conducting alloys, including TiN, TaN, CrNi, CrRu, CuN and the like. These elemental materials may have an amorphous crystalline structure or may have nanocrystalline texture, with individual grain sizes determined by the processing used in their synthesis, which could include: electron-beam or thermal evaporation, ion-beam or magnetron direct current or radio frequency sputtering.

In an embodiment, insulating dielectric 208 is formed to separate top electrode contact 207 from the underlying layers 203-206 and can be formed from various insulating gate dielectrics including SiNx, SiO₂, TEOS and the like, and can be produced by a back-end-of-line compatible chemical vapor deposition or spin coating method.

In an embodiment, selector layer 209 is formed to restrict current flow to a single selected device embedded within a three-dimensional, cross-point array architecture in which each of a multitude of epitaxial memory devices 200 is located at the crossing points of a vertically-layered series of planar arrays of epitaxial memory devices 200. Disposed above each epitaxial functional layer 206 of an epitaxial memory device 200, selector layer 209 includes a resistive threshold material. The threshold behavior enhances the electrical isolation of three-dimensional cross point memory arrays, by restricting current flow unless the selector layer is experiencing an electrical voltage stimulus. This voltage threshold response tends to significantly increase electric current flow into the corresponding epitaxial memory device 200, selecting it for electrical stimulation, or more precisely, for the carrying out of a read or write operation on an individual epitaxial memory device. Unlike, e.g., a diode, selector layer 209 exhibits bipolar operation, allowing or restricting the flow of electrical current from top electrode 207 to bottom electrode 203, or alternatively flowing from bottom electrode 203 to top electrode 207. Typical selector layers are binary chalcogenide glasses composed of one chalcogen element component (S, Se, Te) and a non-chalcogenide component (As, Si, Ge, Zn, In, Al, Sn, Zn, B or C), and can be produced by a back-end-of-line compatible chemical vapor deposition or physical vapor deposition method.

In certain embodiments, the rock salt layer 204 can be formed with a fiber texture. This type of texture, where the crystal grains have a preferred alignment along a specific direction, can be achieved through various deposition techniques, such as sputtering or evaporation. The fiber texture enhances the anisotropic properties of the functional materials, leading to improved performance in specific directions. For instance, in spintronic devices, a fiber-textured rock salt layer promotes spin transport along the fiber direction, reducing spin scattering and increasing spin diffusion lengths, which is beneficial for spintronic device applications.

Alternatively, the rock salt layer 204 can be formed with a biaxial texture, where the crystal grains have a preferred alignment along two orthogonal directions. This texture can be achieved by employing techniques such as ion beam-assisted deposition, where a noble gas ion beam is directed at the film during growth to preferentially etch away misaligned crystallites. The biaxial texture provides balanced properties in two dimensions, which can be advantageous for certain device applications, such as ferroelectric devices, where it leads to more uniform polarization switching behavior and improved device reliability.

In some embodiments, the rock salt layer 204 may comprise a bilayer structure, with a first rock salt layer formed with a fiber texture and a second rock salt layer formed above the first layer. This bilayer structure allows for the combination of the benefits of both fiber and biaxial textures, leading to further improvements in device performance. The second rock salt layer can be formed of the same material as the first layer (homoepitaxy) or a different material, depending on the specific requirements of the device. For example, in resistive switching materials, the combination of textures can promote the formation of more controllable and reliable conducting filaments, enhancing switching characteristics.

The buffer layer 205, grown above the rock salt layer 204, inherits the texture of the underlying rock salt layer. This inheritance of texture ensures that the buffer layer has a similar crystallographic orientation as the rock salt layer, facilitating the epitaxial growth of the functional layer with improved crystal quality and reduced strain.

The epitaxial functional layer 206, grown above the buffer layer 205, inherits the texture of the underlying buffer layer, ensuring that the functional layer has the desired crystallographic orientation for optimal performance. The choice of material for the epitaxial functional layer depends on the specific functionality desired. For spintronic applications, materials such as Heusler alloys or L10-phase intermetallics can be used. For ferroelectric applications, materials such as perovskite oxides can be employed. For resistive switching applications, materials such as Mott insulators or high-entropy oxides can be utilized.

In some embodiments, the article further comprises a second article formed on the same CMOS wafer but without a rock salt layer. This allows for the fabrication of devices with multiple regions having different functionalities and properties. The second article can be engineered to have a perpendicular magnetization orientation relative to the article that includes the rock salt layer, creating a magnetic domain wall that can be exploited for spintronic applications. Alternatively, the article and the second article can be configured to have different resistance levels, enabling the creation of distinct device states for memory or neuromorphic computing applications.

The specific implementation of each element in epitaxially-grown memory device 200 contributes to several technical advantages. The fiber-textured or biaxial-textured rock salt layer enhances the anisotropic properties of the functional materials. The bilayer rock salt structure combines the benefits of both textures. The buffer layer with inherited texture promotes epitaxial growth and improves crystal quality. The epitaxial functional layer with inherited texture has optimal functional properties. The second article without a rock salt layer enables the fabrication of devices with multiple functionalities, and the perpendicular magnetization orientation or different resistance levels create additional opportunities for device design and applications.

Epitaxially-grown memory device 200 can be made of various elements and components that are microfabricated. Elements of epitaxially-grown memory device 200 can be various sizes. Elements of epitaxially-grown memory device 200 can be made of a material that is physically or chemically resilient in an environment in which epitaxially-grown memory device 200 is disposed.

In an embodiment, a method for making a epitaxially-grown memory device 200 includes: providing a CMOS wafer; forming a plurality of contact electrodes on a surface of the CMOS wafer; forming a bottom electrode contact on the surface of the CMOS wafer and in electrical contact with one of the plurality of contact electrodes; forming a rock salt layer above the bottom electrode contact; growing a buffer layer above the rock salt layer; growing an epitaxial functional layer above the buffer layer; forming a top electrode contact above the epitaxial functional layer and configured to convey electrical signals to one of the plurality of contact electrodes; and forming an insulating dielectric between the top electrode contact and the bottom electrode contact. In an embodiment, forming the rock salt layer includes forming the rock salt layer with a fiber texture. In an embodiment, growing the buffer layer includes growing the buffer layer to inherit a texture of the rock salt layer. In an embodiment, growing the epitaxial functional layer includes growing the epitaxial functional layer to inherit a texture of the buffer layer. In an embodiment, the method includes forming a second epitaxially-grown memory device 200 that does not include a rock salt layer on the same CMOS wafer as the epitaxially-grown memory device 200.

Epitaxially-grown memory device 200 can be made in various ways. In an embodiment, with reference to FIG. 5, a process for making epitaxially-grown memory device 200 can include: forming contact electrodes on the surface of a CMOS substrate in electrical contact with two separate CMOS VIAs; forming a bottom electrode in contact with the first of two contact electrodes; forming a rock salt layer above the bottom electrode that exhibits either fiber texture or biaxial texture through the simultaneous ion beam bombardment during layer formation and optionally forming additional homoepitaxial rock salt layer above the ion-beam-bombarded rock salt layer; forming a buffer layer above the rock salt layer; forming epitaxial functional layers above the buffer layer; forming a top electrode contact above the epitaxial functional layers; defining the lateral extent of the bottom electrode, rock salt layer, epitaxial functional layers, and top electrode; and forming a patterned dielectric to electrically isolate the bottom electrode, rock salt layer, epitaxial function layers from the connection between the top electrode contact and second of two contact electrodes.

In an embodiment, with reference to FIG. 5, a process for making epitaxially-grown memory device 200 can include: placing a CMOS substrate 201 with contact electrodes 202 and bottom electrode contact 203 in physical vapor deposition chamber step 705; forming a rock salt layer 204 by physical vapor deposition step 710; applying texture in rock salt layer 204 step 715; applying rock salt layer 204 microstructure improvement anneal step 720; forming a homoepitaxial overlayer in rock salt layer 204 step 725; forming buffer layers 205 above rock salt layer 204 step 730; applying buffer layers 205 microstructure improvement anneal step 735; forming epitaxial functional layers 206 above buffer layers 205 step 740; applying epitaxial functional layers 206 microstructure improvement anneal step 745; forming top electrode layer 207 above epitaxial functional layers 206 step 750; forming pillar mask above top electrode layer 207 step 755; defining lithographically pillars down to top of bottom electrode contact 203 step 760; forming bottom electrode mask for patterning of bottom electrode contact 203 step 765; defining lithographically bottom electrode contact 203, step 770; forming encapsulation insulating dielectric layer 208, step 775; forming top electrode contact 207 mask, step 780; and defining lithographically top electrode contact 207, step 785.

It is contemplated that making CMOS wafer 201 can include selectively patterning the surface of CMOS wafer 201 with rock salt layer 204 to realize epitaxial memory devices 200 with alternating regions of fiber textured or biaxially textured epitaxial functional layer 207 and untextured or polycrystalline regions of epitaxial functional layer 207. In an embodiment, the process for making CMOS wafer 201 includes applying rock salt layer 204 microstructure improvement anneal step 720; and forming a homoepitaxial overlayer in rock salt layer 204 step 725. In an embodiment, with reference to FIG. 6 and FIG. 7, selective area epitaxy is accomplished by the deposition of patterned rock salt layers 204 onto substrate 201, which can be accomplished by an additive process (e.g., deposition through a shadow mask 210 above substrate 201 or by a lift-off technique, or deposition on top of a photo-or electron beam resistive layer 211 deposited onto the substrate above bottom electrode contact layer 203). In another embodiment, with reference to FIG. 8, selective area epitaxy is accomplished by the deposition of patterned rock salt layers 204 onto substrate 201 by a subtractive process (e.g., chemical or ion beam etching of regions left unmasked by a photo-or electron beam resistive layer 211 deposited above rock salt layers 204). In an embodiment, with respect to FIG. 9, epitaxial functional layer 206 inherits the texture (fiber or biaxial) and functionality controlled regions 212 in regions where substrate 201 has been selectively coated with patterned rock salt layers 204, and likewise will not inherit a preferred fiber or biaxial texture in regions where substrate 201 has not been selectively coated with patterned rock salt layers 204 and are therefore sitting directly above bottom contact 203.

The process for forming an epitaxially-grown device on CMOS includes disposing a CMOS substrate into a physical vapor deposition chamber. A rock salt layer is formed above the CMOS substrate using a physical vapor deposition technique, among which advantageous properties of the rock salt layer can be realized using electron-beam and thermal evaporation, but also using ion beam and direct current and magnetron sputter deposition techniques. Under certain deposition conditions, <100> fiber texture of the rock salt layer can be realized, such that (see FIG. 10 and FIG. 11) the crystallite facets are mutually oriented with the <100> facets facing outward perpendicular to the film plane. Further texturing can be applied to the rock salt layer to develop a preferred facet orientation within the film plane (see e.g. FIG. 12(a) and FIG. 12(b)) through ion beam assisted deposition (IBAD). The IBAD process requires etching away misaligned crystallites at the same time that the thin film is being formed on the CMOS substrate and is graphically depicted in FIG. 13. Deposition- and etch-induced microstructural imperfections after the IBAD rock salt layer growth are mitigated by a microstructural improvement anneal step. An additional homoepitaxial rock salt layer may be grown using physical vapor deposition without an ion assist beam to manipulate the grain size of the rock salt layer. Following the rock salt layer texture definition and optional homoepitaxial rock salt layer, a buffer layer may be grown to promote adhesion to the rock salt layer and/or mitigate lattice mismatch between the rock salt layer and the epitaxial functional layers. The microstructure of the buffer layers may be improved by a microstructural improvement anneal step, to reduce roughness and relax crystalline stresses at the surface of the buffer layer film. The epitaxial functional layers are formed above the buffer layers and inherit the mutual crystalline texture of the buffer layers and the rock salt layers below. Additional crystallization and/or deposition-induced stresses may be mitigated by a microstructural improvement anneal step. A top electrode is then formed above the epitaxial functional layers followed by several steps of patterning and isolation, including: forming the pillar mask and lithographically etching down to the bottom electrode layer; forming the bottom electrode mask and lithographically defining the bottom electrode; forming an insulating dielectric layer to separate the top electrode, pillar and bottom electrode; and finally forming the top electrode and bottom electrode contacts for electrical stimulation.

According to step 705, a CMOS wafer 201 is loaded into a physical vapor deposition chamber either through transfer directly from atmosphere into the chamber and subsequent pump down or transfer into an intermediate chamber (a so-called load-lock chamber) at atmosphere that can be quickly evacuated before transferring the wafer into an evacuated physical vapor deposition chamber.

According to step 710, the rock salt layer 204 is formed by physical vapor deposition. Rock salt layers 204 are formed above the bottom electrode contact 203 and are engineered to possess either fiber texture or biaxial texture. Rock salt layers are a thin film complex consisting of an assembly of small crystallites that are oriented with either (see FIG. 12): a single preferred facet orientation perpendicular to the film plane with random in-plane orientation, or fiber texture; or a single preferred facet orientation perpendicular to the film plane and a single preferred facet orientation within the film plane of the layers, or biaxial texture. The size of the individual constituent crystallites scales in proportion with the thickness of rock salt layers 204. Rock salt layers could be composed of an insulating alloy, including TiO, VO, MgO, MnO, NiO, CoO, ZnO and several combinations thereof. It could alternatively be derived from several conducting species, including TiN, TaN, ZrN, HfN, VN and WN, The varying chemical composition leads to variation in the underlying lattice constant from below 0.42 nm to in excess of 0.45 nm, which can be advantageous in lattice matching directly with epitaxial functional layers 206 or indirectly through buffer layers 205. Rock salt layers are grown using physical vapor deposition techniques, including electron-beam or thermal evaporation, ion-beam or magnetron direct current or radio frequency sputtering and derive a fiber texture due to surface energy minimization of <100> oriented facets during thin film growth.

Rock salt layers can be grown with deposition rates ranging from 0.001 nm s−1 to 1 nm s−1, with typical growth rates ranging from 0.005 nm s−1 to 0.1 nm s−1. Arriving rock salt atomic species typically possess less than 1 eV of energy when deposited using thermal or electron beam evaporation, and typically between 1 eV and 100 eV energy when deposited using direct current or radio frequency magnetron sputtering or ion beam sputtering. Typically intermediate arriving energies deliver needed energy for the thermodynamic transition of the spherical rock salt particles into fiber-textured crystallites, while higher energy arriving atoms tend to generate defects in the crystallites and reduce the degree of crystallinity or even amorphized the rock salt layer entirely. Rock salt layers can be grown while the CMOS substrate is optionally undergoing continuous azimuthal rotation where needed to improve uniformity for certain deposition sources with an inhomogeneous deposition profile across the CMOS substrate.

The background atmosphere while forming the rock salt layer can be as low as 1 microPascal for evaporation, and between 0.01 Pa to 0.4 Pa for sputtering. In the higher pressure conditions the predominant partial pressure is the noble gas used in sputtering (which can include Ne, Ar, Kr, and Xe).

With rock salt deposition alone, fiber texture in the rock salt layer is conveyed to an overlaid film such that a strong degree of out-of-plane alignment can be realized, with a narrow distribution of misaligned <100> crystallites in the buffer layer within 1-2 degrees away from the film surface (see, e.g., FIG. 14).

According to step 715, biaxial texture is conveyed to the rock salt layer 204 under the influence of an ion assist beam simultaneously during deposition step 710. The ion assist beam is a Kauffman-type end Hall ion source with three grids used to control the beam lateral profile and beam energy. The ion assist beam is directed at the CMOS substrate surface and at an angle 45 degrees above the substrate surface. Due to the channeling of <101> facets in rock salt crystallites, the ion beam will not interact with crystallites whose <101> facet is oriented 45 degrees above the surface normal. Crystallites whose <101> orientation is misaligned with the incident beam are preferentially etched, removing them from the growing rock salt film. The resultant remaining crystallites also have their <001> facets oriented along the surface normal and have their <100> facets aligned in the direction of the assist beam, with an associated four-fold symmetry within the plane (see, e.g., FIG. 12). The dominant in-plane and out-of-plane mutual crystallite texturing makes the IBAD rock salt layer a near-ideal replacement to a bulk single crystal for the introduction of an epitaxial growth template. Control of the alignment of the IBAD beam with respect to the CMOS surface normal is critical to optimize the mutual in-plane and out-of-plane texturing of the rock salt film—the degree of misalignment from the <101> channeling direction at 45 degrees will begin to etch crystallites with the desired biaxial texture, leaving an oblique texture with regards to the in-plane and out-of-plane axes of the CMOS substrate. Control of the etch rate relative to the deposition rate is also highly critical, as the assist beam needs to etch the growing film nearly as fast as it is arriving at the CMOS substrate surface. In practice, an average etch rate of approximately ninety (90 %) per cent of the deposition rate is advantageous for realizing a high degree of biaxial texture in terms of mutually narrow distributions of the <001> facets normal to the film plane and <100> facets along the four-fold symmetry axis within the film plane (see FIG. 12). An etch rate as high as ninety-five (95%) per cent of the deposition rate has shown further narrowing of the facet distributions and highlights the significant role played by the ion assist beam. Also significant is the film thickness. Films greater than 10 nm in thickness tend to develop polycrystalline variants, losing the original fiber texture. Furthermore, films between 1 nm and 5 nm tend to have the narrowest facet distributions within the plane and out-of-the-plane, highlighting the need for ultrathin rock salt biaxial template layers for epitaxial growth on CMOS.

According to step 720, remnant stress and roughness caused by the rock salt deposition and the ion beam assist are mitigated by a microstructure improvement anneal. This is a thermal processing step that takes place in vacuum, but could also take place in a small partial pressure (0.01 Pa or lower) of nitrogen gas or oxygen gas if the rock salt layer is a nitride or an oxide, respectively. Typical temperature for this thermal processing step range from 200 C to 600 C, but can take place at CMOS compatible temperatures ranging from 200 C to 400 C, and typically take place between 300 C and 400 C. Typical duration for this thermal processing step ranges from 30 s to 60 mins, but more typically ranges between 10 mins and 30 mins.

According to step 725, an optional homoepitaxial rock salt layer is formed above the ion beam assisted deposition of an ultrathin rock salt layer. The homoepitaxial rock salt layer can be formed using physical vapor deposition techniques, including electron beam or thermal evaporation, direct current or radio frequency magnetron sputtering, or ion beam sputtering. The thickness of the homoepitaxial rock salt layer may range from 5 nm to 50 nm, but typically between 10 nm and 20 nm and for the purpose of manipulating the electrical conductivity, roughness, and grain size of the resultant rock salt layers 204.

According to step 730, buffer layers 205 are formed above the rock salt layers 204. The buffer layers can be formed using physical vapor deposition techniques, including electron beam or thermal evaporation, direct current or radio frequency magnetron sputtering, or ion beam sputtering. The thickness of the buffer layers 205 may range from 5 nm to 50 nm, but typically between 10 nm and 20 nm and for the purpose of manipulating the electrical conductivity, roughness, grain size and lattice mismatch of the resultant buffer layers 205 with respect to the underlayer rock salt layers 204 and the subsequent epitaxial functional layers 206. In certain embodiments, the buffer layers 205 consist of two or more layers of distinct chemical composition, with at least one first layer serving as an adhesion layer to the rock salt layer 204 due to advantageous chemical bonding and subsequent layers serving to optimize the electrical conductivity, lattice mismatch, interfacial diffusivity or functional properties like work function, spin diffusion length or the like.

According to step 735, stresses and roughness in the buffer layers 205 can be healed by a microstructure improvement anneal. This is a thermal processing step that takes place in vacuum but could also take place in a small partial pressure (0.01 Pa or lower) of nitrogen gas or oxygen gas if the buffer layer is a nitride or an oxide, respectively. Typical temperatures for this thermal processing step range from 200 C to 600 C but can take place at CMOS compatible temperatures ranging from 200 C to 400 C, and typically take place between 300 C and 400 C. Typical duration for this thermal processing step ranges from 30 s to 60 mins, but more typically ranges between 10 mins and 30 mins.

According to step 740, epitaxial functional layers 206 are formed above buffer layers 205. Epitaxial functional layers 206 may take the form of spintronic materials, ferroelectric materials, or resistive switching materials. The epitaxial texture will result in improved performance of the functional layers, which for spintronic/topological materials could manifest in higher tunneling magnetoresistance, higher non-volatile storage times for smaller size memory devices, and lower high-frequency losses; for ferroelectric materials it could manifest in higher polarization, more reliable polarization switching behavior, less fatigue/failure characteristics, non-destructive read, and better reliability at smaller device size; for resistive materials it could manifest in more controllable formation and annihilation of conducting filaments, coherent Mott transitions and more reliable switching behavior. The epitaxial functional layers 206 are derived from a class of materials, including cubic or pseudo-cubic spintronic/topological materials (X_{2}YZ and X_{3}Z Heusler alloys and L1_{0}-phase intermetallics to name a few), tetragonal complex oxides for ferroelectric materials, and Mott insulators and high entropy oxides for resistive materials. The epitaxial functional layer can be formed using physical vapor deposition techniques, including electron beam or thermal evaporation, molecular beam epitaxy, pulsed laser deposition, direct current or radio frequency magnetron sputtering, or ion beam sputtering. The thickness of the functional epitaxial layer may range from 5 nm to 50 nm, but typically ranges between 10 nm and 20 nm.

According to step 745, stresses and roughness in the epitaxial functional layers 206 can be healed by a microstructure improvement anneal. This is a thermal processing step that takes place in vacuum but could also take place in a small partial pressure (0.01 Pa or lower) of nitrogen gas or oxygen gas if the epitaxial functional layers include a nitride or an oxide, respectively. Typical temperatures for this thermal processing step range from 200 C to 600 C but can take place at CMOS compatible temperatures ranging from 200 C to 400 C, and typically take place between 300 C and 400 C. Typical duration for this thermal processing step ranges from 30 s to 60 mins, but more typically ranges between 10 mins and 30 mins.

According to step 750, the top electrode layer 207 is formed above the epitaxial functional layers 206. This layer can be formed using physical vapor deposition techniques, including electron beam or thermal evaporation, molecular beam epitaxy, pulsed laser deposition, direct current or radio frequency magnetron sputtering, or ion beam sputtering. The thickness of the top electrode layer may range from 5 nm to 100 nm, but typically ranges between 10 nm and 50 nm

According to step 755, a pillar mask is formed above the top electrode layer 207. This mask serves to define the diameter of a pillar in the twelfth step, 760, that includes the epitaxial functional layers 206, buffer layers 205, rock salt layers 204 and top electrode 207. The diameter of the pillar can range from 3 nm to 10,000 nm, but typically ranges from 20 nm to 50 nm for prospective devices compatible with ultrahigh density arrays of CMOS transistors.

According to step 765, a bottom electrode mask is formed above the top electrode layer 207. This mask serves to define the diameter of the bottom electrode in the fourteenth step, 770. The diameter of the bottom electrode can range from 10 nm to 50,000 nm, but typically ranges from 20 nm to 100 nm for prospective devices compatible with ultrahigh density arrays of CMOS transistors.

According to step 775, insulating dielectric 208 is formed over the CMOS substrate to encapsulate the pillars and to avoid short-circuiting between top electrode and bottom electrode, or between top or bottom electrode and intervening layers 204-206, in a pillar structure; and

According to step 780, a top electrode mask is formed above the insulating dielectric 208 to expose the top electrode and lithographically define in the seventeenth step, 785, contact from the top electrode to contact electrode 202..

The epitaxially-grown memory device 200 also can be made as a prototype testing vehicle before growth on CMOS by: forming a bottom electrode on an unpatterned semiconductor Si wafer or a Si wafer with its native oxide or a Si wafer with chemical-vapor-deposited SiNx or SiO2 or with thermally oxidized SiO2; forming a rock salt layer above the bottom electrode that exhibits either fiber texture or biaxial texture through the simultaneous ion beam bombardment during layer formation and optionally forming additional homoepitaxial rock salt layer above the ion-beam-bombarded rock salt layer; forming a buffer layer above the rock salt layer; forming epitaxial functional layers above the buffer layer; forming a top electrode contact above the epitaxial functional layers; patterning the underlying deposited layers into individual micron-scale or nanometer-scale pillar devices using appropriate optical or electron-beam based lithography techniques combined with appropriate chemical or physical etch techniques; depositing dielectric insulation onto the patterned array of pillar devices; and forming electrical contacts to the top electrode and bottom electrode for electrical stimulation.

The epitaxially-grown memory device 200 can be made as a vehicle for epitaxial cross-point memory arrays grown on CMOS by: forming a first series of N parallel contact electrode bit lines 203 on the surface of a CMOS substrate 201 in electrical contact with N separate CMOS VIA contact electrodes 202; forming a first rock salt layer 204 above the bottom electrode 203 that exhibits either fiber texture or biaxial texture through the simultaneous ion beam bombardment during layer formation and optionally forming additional homoepitaxial rock salt layer above the ion-beam-bombarded rock salt layer; forming a first buffer layer 205 above the rock salt layer 204; forming a first epitaxial functional device 206 above the buffer layer 205; forming a first selector layer 209 above the epitaxial functional device 206 that resists current sneak-paths while individual epitaxial functional device 206 is not selected for electrical stimulation; forming a first top electrode contact 207 above the selector layer 209; patterning the first set of underlying deposited layers into nanometer-scale pillars; depositing a first dielectric insulation 208 onto the patterned array of pillar devices; forming a first series of N parallel contact electrode word lines above the top electrode contact 207 and running perpendicular to the N parallel bit lines 203 creating N×N junctions to the N×N epitaxial functional devices; forming a second rock salt layer 204 above the N parallel contact electrode word lines 207 that exhibits either fiber texture or biaxial texture through the simultaneous ion beam bombardment during layer formation and optionally forming additional homoepitaxial rock salt layer above the ion-beam-bombarded rock salt layer; forming a second buffer layer 205 above the rock salt layer; forming a second series of epitaxial functional layers 206 above the buffer layer; forming a second selector layer 209 above the epitaxial functional device that resists current sneak-paths while individual epitaxial functional device 206 is not selected for electrical stimulation; forming a second top electrode contact 207 above the selector layer; patterning a second series the underlying deposited layers into nanometer-scale pillars; depositing a second layer of dielectric insulation 208 onto the patterned array of pillar devices; forming a second series of N parallel contact electrode bit lines 203 above the top electrode contact 207 and running perpendicular to the N parallel word lines creating N×N junctions to the N×N epitaxial functional devices 206; and repeating above steps until N×N×N epitaxial functional devices have been formed using the forming of N repeating planes of N×N epitaxial functional device arrays connected at the intersections of N×N bit lines and N×N word lines.

Processes disclosed herein can be used for making high quality devices with superior electronic behavior, yield and uniformity that are compatible with CMOS. The resulting heterogeneous technologies could be used for digital memory storage, but the most exciting application is neuromorphic computing, in particularly hardware for neural networks and artificial intelligence.

With reference to FIG. 3, a CMOS wafer includes a series of bulk crystalline Si, amorphous dielectric isolation, and polycrystalline metal interconnections between electronic devices. Any new device that would be integrated with the circuitry of a CMOS wafer would have a proximal interface with either amorphous dielectric or polycrystalline metal. An epitaxial MgO buffer layer, crystallized into the ordered rock salt phase and with biaxial <100> orientation, delivers a flexible template for monolithic growth of a wide range of crystalline materials for heterogeneous integration into memory and logic devices on CMOS. In practice, bit lines (Bitline) and word lines (WL) would be charged in order to generate an electrical connection with an individual epitaxial device formed through an epitaxial MgO buffer layer.

In an embodiment, with reference to FIG. 1, epitaxially-grown memory device 200 for device/CMOS integration includes a high quality barrier/buffer and active films depending on the desired device structure and behavior. Here, epitaxially-grown memory device 200 includes a buffer layer of a material that preferentially wants to crystallize at low CMOS-compatible temperatures, even when deposited on amorphous substrates. Rock salt, e.g., magnesium oxide (MgO), is a material for this purpose, which preferentially stabilizes in <100>. Embodiments can include growth of high quality, e.g. biaxially-textured, MgO (biaxial-MgO) films on ultra-smooth bottom electrode material, such as TiN or directly on the SiO₂ gate dielectric material between metallized vias at the surface of CMOS wafers. One example of such a device is the resistive switching (or memristor) device, which has a two-terminal design with a layer (or stack) of oxide(s) sandwiched between two electrodes. In an embodiment, the device is the magnetic switching or (magnetic tunnel junction) device, which also has a two-terminal design with a series of ferromagnetic layers with an insulating oxide separating one pair of ferromagnets, all of which are similarly sandwiched between two electrodes. Using the biaxial-MgO films, the entire stack may be deposited all at once. An ultra-smooth bottom electrode material, the barrier (e.g. biaxial-MgO), active film(s) and top electrode films will be deposited in the same sputtering step, following by patterning, and controlled ion milling for lithographic patterning.

Epitaxially-grown memory device 200 and process for making epitaxially-grown memory device 200 have numerous advantageous such as making high quality devices with superior electronic behavior, yield and uniformity that are compatible with CMOS. The resulting heterogeneous technologies can be used for digital memory storage, neuromorphic computing, in hardware for neural networks and artificial intelligence, and the like.

The epitaxially-grown memory device 200 can be used by: forming the smallest diameter epitaxial functional memory device 206 size whose superior electronic behavior, yield and uniformity can enable high areal device density with narrow device pillar diameter; forming the highest CMOS transistor density/smallest transistor size that can generate adequate read and write current to electrically stimulate each epitaxial functional memory device 206; using random access control from CMOS access transistors to electrically stimulate reading and/or writing the binary digital state of any epitaxial functional memory device 206 in the array; and storing critical data in the digital random access memory array of epitaxial functional memory devices 206 for enterprise or other high value computing operations.

The epitaxially-grown memory device 200 also can be used by: forming the smallest diameter epitaxial functional device 206 size whose superior electronic behavior, yield and uniformity can enable high areal device density with narrow device pillar diameter; forming the highest CMOS transistor density/smallest transistor size that can generate adequate read and write current to electrically stimulate each device as a synaptic component of a neuromorphic computing hardware array; and carrying out neural network and artificial intelligence compute operations in this hardware for neuromorphic computing, including electrically stimulating epitaxial functional device rows and columns sequentially, to carry out training and other neuromorphic compute operations

The epitaxially-grown memory device 200 also can be used by: forming the smallest diameter epitaxial functional device 206 size whose superior electronic behavior, yield and uniformity can enable high areal device density with narrow device pillar diameter; forming a first array of bit lines from bottom electrode contacts 203 to grow an array of epitaxial functional devices 206 above rock salt layers 204 and integrated with selector layers 209 to minimize current sneak paths; forming dielectric isolation layer 208 between pillars of bit lines 203 and word lines 207; forming a second array of word lines from top electrode contacts 207 to grow a second array of epitaxial functional devices 203 above a second array of rock salt layers 204 and selector layers 209 to minimize current sneak paths; forming a second dielectric isolation layer 208 between pillars of bit lines 203 and word lines 207; forming remaining arrays of dielectric isolation layers 208, bit lines 203 and word lines 207 to grow additional arrays of rock salt layers 204, epitaxial functional devices 206 and selector layers 209 to minimize current sneak paths; implementing hardware that can take advantage of three-dimensionally stacked memory arrays with concomitant gains in bandwidth and reduced interconnect time delays and wasted power dissipation.

The epitaxially-grown memory device 200 also can be used by: forming rock salt layers 204 on large scale (>200 mm diameter) unpatterned semiconductor wafers to evaluate tools and processes for epitaxial growth of epitaxial functional memory devices at scales unavailable with bulk substrates; testing epitaxial functional memory devices 206 as continuous films using x-ray diffraction, electron diffraction and microscopy, electrical, magnetic and/or optical measurements to build up processing-structure-function relationships; and patterning two-terminal epitaxial functional memory devices 206 as metrological devices to relate processing-structure-function to performance, including read and write energy, read and write speed, endurance and non-volatility, among other things.

Various embodiments include:
Embodiment 1. An epitaxially-grown memory device 200 comprising: a CMOS substrate; a rock salt layer, e.g., magnesium oxide (MgO), dipsoed on the CMOS substrate; a buffer layer disposed on the rock salt layer; an active film disposed on the buffer layer; and a top electrode disposed on the active film.
Embodiment 2. The epitaxially-grown memory device 200 of embodiment 1, wherein the rock salt layer of MgO is biaxially textured.
Embodiment 3. The epitaxially-grown memory device 200 of embodiment 1, wherein the active film is a resistive switching (or memristor) film.
Embodiment 4. The epitaxially-grown memory device 200 of embodiment 1, wherein the active film is a magnetic tunnel junction (MTJ) film.
Embodiment 5. The epitaxially-grown memory device 200 of embodiment 1, wherein the top electrode is a metal electrode.
Embodiment 6. The epitaxially-grown memory device 200 of embodiment 1, wherein the top electrode is a semiconductor electrode.
Embodiment 7. The epitaxially-grown memory device 200 of embodiment 1, wherein the CMOS substrate is a silicon substrate.
Embodiment 8. The epitaxially-grown memory device 200 of embodiment 1, wherein the CMOS substrate is a gallium arsenide substrate.
Embodiment 9. The epitaxially-grown memory device 200 of embodiment 1, wherein the CMOS substrate is a diamond substrate.
Embodiment 10. The epitaxially-grown memory device 200 of embodiment 1, wherein the rock salt layer of MgO is grown by atomic layer deposition (ALD).
Embodiment 11. The epitaxially-grown memory device 200 of embodiment 1, wherein the rock salt layer of MgO is grown by sputter deposition.
Embodiment 12. The epitaxially-grown memory device 200 of embodiment 1, wherein the rock salt layer of MgO is grown by chemical vapor deposition (CVD).
Embodiment 13. The epitaxially-grown memory device 200 of embodiment 1, wherein the active film is grown by ALD.
Embodiment 14. The epitaxially-grown memory device 200 of embodiment 1, wherein the active film is grown by sputter deposition.
Embodiment 15. The epitaxially-grown memory device 200 of embodiment 1, wherein the active film is grown by CVD.
Embodiment 16. The epitaxially-grown memory device 200 of embodiment 1, wherein the top electrode is grown by ALD.
Embodiment 17. The epitaxially-grown memory device 200 of embodiment 1, wherein the top electrode is grown by sputter deposition.
Embodiment 18. The epitaxially-grown memory device 200 of embodiment 1, wherein the top electrode is grown by CVD.
Embodiment 19. The epitaxially-grown memory device 200 of embodiment 1, wherein the article is used in a memory device.
Embodiment 20. The epitaxially-grown memory device 200 of embodiment 1, wherein the article is used in a logic device.
Embodiment 21. A method of fabricating an epitaxially-grown memory device 200 comprising the steps of: providing a CMOS substrate; depositing a rock salt layer of rock salt (e.g., MgO) on the CMOS substrate; patterning the rock salt layer; depositing a first active layer on the patterned rock salt layer; patterning the first active layer; depositing a second active layer on the patterned first active layer; patterning the second active layer; depositing a top electrode on the patterned second active layer; wherein the buffer layer is biaxially textured.
Embodiment 22. The method of embodiment 21, wherein the first active layer is a resistive switching layer.
Embodiment 23. The method of embodiment 21, wherein the second active layer is a magnetic tunnel junction layer.
Embodiment 24. The method of embodiment 21, wherein the CMOS substrate is a silicon wafer.
Embodiment 25. The method of embodiment 21, wherein the buffer layer is grown by atomic layer deposition.
Embodiment 26. The method of embodiment 21, wherein the first active layer is grown by sputtering.
Embodiment 27. The method of embodiment 21, wherein the second active layer is grown by sputtering.
Embodiment 28. The method of embodiment 21, wherein the top electrode is made of platinum.
Embodiment 29. The method of embodiment 21, wherein the top electrode is made of gold.
Embodiment 30. The method of embodiment 21, wherein the top electrode is made of copper.
Embodiment 31. The method of embodiment 21, wherein the rock salt layer has a thickness of from 1 to 10 nanometers.
Embodiment 32. The method of embodiment 21, wherein the first active layer has a thickness of from 1 to 10 nanometers.
Embodiment 33. The method of embodiment 21, wherein the second active layer has a thickness of from 1 to 10 nanometers.
Embodiment 34. The method of embodiment 21, wherein the top electrode has a thickness of from 1 to 10 nanometers.
Embodiment 35. The method of embodiment 21, wherein the buffer layer has a biaxial texture with a preferred orientation of <100>.
Embodiment 36. The method of embodiment 21, wherein the first active layer has a biaxial texture with a preferred orientation of <100>.
Embodiment 37. The method of embodiment 21, wherein the second active layer has a biaxial texture with a preferred orientation of <100>.
Embodiment 38. The method of embodiment 21, wherein the top electrode has a biaxial texture with a preferred orientation of <100>.
Embodiment 39. The method of embodiment 21, wherein the patterning step is performed using a photolithography process.
Embodiment 40. The method of embodiment 21, wherein the patterning step is performed using an electron beam lithography process.
Embodiment 41. A method of operating an epitaxially-grown memory device 200 comprising: providing the epitaxially-grown memory device 200 comprising a CMOS substrate, a rock salt layer comprsing rock salt (e.g., MgO) disposed on the CMOS substrate, a first active layer on the rock salt layer, a second active layer on the first active layer, and a top electrode on the second active layer; applying a voltage to the top electrode; applying a current to the top electrode; and measuring a change in resistance between the top electrode and the CMOS substrate; wherein the rock salt layer is biaxially textured.
Embodiment 42. The method of embodiment 41, wherein the first active layer is a resistive switching layer.
Embodiment 43. The method of embodiment 41, wherein the second active layer is a magnetic tunnel junction layer.
Embodiment 44. The method of embodiment 41, wherein the CMOS substrate is a silicon wafer.
Embodiment 45. The method of embodiment 41, wherein the buffer layer is grown by atomic layer deposition.
Embodiment 46. The method of embodiment 41, wherein the first active layer is grown by sputtering.
Embodiment 47. The method of embodiment 41, wherein the second active layer is grown by sputtering.
Embodiment 48. The method of embodiment 41, wherein the top electrode is made of platinum.
Embodiment 49. The method of embodiment 41, wherein the top electrode is made of gold.
Embodiment 50. The method of embodiment 41, wherein the top electrode is made of copper.
Embodiment 51. The method of embodiment 41, wherein the rock salt layer has a thickness of from 1 to 10 nanometers.
Embodiment 52. The method of embodiment 41, wherein the first active layer has a thickness of from 1 to 10 nanometers.
Embodiment 53. The method of embodiment 41, wherein the second active layer has a thickness of from 1 to 10 nanometers.
Embodiment 54. The method of embodiment 41, wherein the top electrode has a thickness of from 1 to 10 nanometers.
Embodiment 55. The method of embodiment 41, wherein the rock salt layer has a biaxial texture with a preferred orientation of <100>.
Embodiment 56. The method of embodiment 41, wherein the first active layer has a biaxial texture with a preferred orientation of <100>.
Embodiment 57. The method of embodiment 41, wherein the second active layer has a biaxial texture with a preferred orientation of <100>.
Embodiment 58. The method of embodiment 41, wherein the top electrode has a biaxial texture with a preferred orientation of <100>.
Embodiment 59. The method of embodiment 41, wherein the voltage applied to the top electrode is a first voltage; measuring a change in resistance between the top electrode and the CMOS substrate in response to the first voltage; applying a second voltage to the top electrode; and measuring a change in resistance between the top electrode and the CMOS substrate in response to the second voltage; wherein the change in resistance in response to the second voltage is different from the change in resistance in response to the first voltage.
Embodiment 60. The method of embodiment 41, wherein the method is ssed to program a memristor.
Embodiment 61. A method for forming an epitaxially-grown thin film monolithically, the method comprising: depositing on a substrate a layer of a material that preferentially crystallizes at a low temperature compatible with complementary metal-oxide semiconductor (CMOS)-chip circuitry; and bombarding the deposited layer with an energetic ion beam directed obliquely at the substrate surface such that the crystalized material is oriented biaxially with the plane of the ion beam.
Embodiment 62. The method of embodiment 61, wherein the ion beam is comprised of argon ions.
Embodiment 63. The method of embodiment 61, wherein the deposited material comprises magnesium oxide.
Embodiment 64. The method of embodiment 61, further comprising overlaying the biaxially-oriented crystalline layer with an active film.
Embodiment 65. The method of embodiment 61, wherein the substrate is an electrode or electrode material.
Embodiment 66. The method of embodiment 65, wherein the electrode material is titanium nitride (TiN).
Embodiment 67. The method of embodiment 61, wherein the substrate is dielectric material on the surface of a complementary metal-oxide semiconductor (CMOS) wafer.
Embodiment 68. A resistive switching or memristor device, comprising at least one a layer of an epitaxially-grown monolithic thin film interposed between two electrodes.
Embodiment 69. The resistive switching or memristor device of embodiment 68, wherein the thin film is produced by the method of embodiment 1.
Embodiment 70. A magnetic switching or magnetic tunnel junction device, comprising at least one layer of an epitaxially-grown monolithic thin film separating two magnetic layers and a mechanism to pin the polarization of at least one of the magnetic layers in a fixed direction.
Embodiment 71. The magnetic switching or magnetic tunnel junction device of embodiment 70, wherein the thin film is produced by the method of embodiment 1.
Embodiment 72. A complementary metal-oxide semiconductor (CMOS) comprising: a CMOS wafer; a bottom electrode; at least one layer of an epitaxially-grown thin film; at least one layer of an active film; and a top electrode, wherein the at least one layer of an epitaxially-grown thin film and the at least one layer of an active film are interposed between the bottom electrode and top electrode, and the CMOS wafer supports the bottom electrode.

The following are incorporated by reference herein in their entirety:
L. A. Zepeda-Ruiz and D. J. Srolovitz, “Effects of ion beams on the early stages of MgO growth,” J. Appl. Phys., vol. 91, no. 12, p. 10169, 2002, doi: 10.1063/1.1479471.
V. Matias and R. H. Hammond, “Ion beam induced crystalline texturing during thin film deposition,” Surface and Coatings Technology, vol. 264, pp. 1-8, February 2015, doi: 10.1016/j.surfcoat.2014.12.018.
A. K. Sharma, A. Kvit, and J. Narayan, “Growth of single crystal MgO on TiN/Si heterostructure by pulsed laser deposition,” Journal of Vacuum Science & Technology A: Vacuum, Surfaces, and Films, vol. 17, no. 6, pp. 3393-3396, November 1999, doi: 10.1116/1.582071.

The articles and processes herein are illustrated further by the following Examples, which are non-limiting.

### EXAMPLES

### Example 1

We have grown both fiber-textured and biaxially-textured MgO as a rock salt layer 204 for the epitaxial growth of functional spintronic devices. The rock salt layer 204 is grown directly above a semiconductor wafer without CMOS electrodes for the purpose of prototyping. We use a two component buffer layer 205 including a Cr adhesion layer followed by a Pt buffer layer, grown sequentially above MgO rock salt layers. The fiber-textured MgO film has been grown by radio-frequency magnetron sputtering but also by ion beam sputtering using a Kaufmann-style Ar\hat{ }{+} ion gun. The biaxially-textured MgO was grown exclusively using a dual-ion beam technique, combining ion beam sputtering using a Kaufmann-style Ar\hat{ }{+} ion gun to sputter a ceramic MgO target and a second Kaufmann-style Ar\hat{ }{+} ion gun directed a 45 degrees above the surface of the semiconductor wafer. As the spintronic device 206, we have grown an L10 FePd intermetallic alloy, and also a Co2MnSi Heusler alloy. We employed a thin (2 nm) MgO barrier layer for tunneling magnetoresistance and tunneling spin-transfer-torque for electrically stimulating read and write operations on this device, respectively. To test the effect of the biaxial and fiber texturing on the films, we carried out out-of-plane and in-plane x-ray diffraction on the thick Cr buffer layer. We grew the buffer layer 205 and spintronic device 206 simultaneously on a fiber-textured and biaxially-textured MgO rock salt layer 204, as well as on a polycrystalline MgO rock salt layer 204 with neither fiber nor biaxial texture, grown by radio frequency magnetron sputtering, and additionally on a bulk MgO(001) crystal substrate. We did not observe any texturing of the Cr buffer layer 205—either in-plane or perpendicular—when grown on the polycrystalline MgO rock salt layer. We found that the Cr buffer layer 205 derived out-of-plane texture with slightly broader facet orientation distribution when compared to a Cr film grown on a bulk MgO substrate for both fiber-texture and biaxially textured MgO rock salt layer 204. Similarly, the Cr buffer layer 205 derived in-plane texture with four-fold symmetry, with slightly broader facet orientation distribution when compared to a Cr film grown on a bulk MgO substrate but only for the biaxially textured MgO rock salt layer 204, consistent with the absence of preferred in-plane texture direction for the fiber-textured MgO rock salt layer 204.

### Example 2

We have grown fiber-textured TiN as a rock salt layer 204 for the epitaxial growth of functional memristive devices. The rock salt layer 204 is grown directly above a semiconductor wafer without CMOS electrodes for the purpose of prototyping. In this working example we looked exclusively at the fiber-textured TiN layer, grown by ion beam sputtering using a Kaufmann-style Ar⁺ ion gun.

### Example 3

An ultrathin ion beam sputtered MgO or TiN rock salt layer inherits biaxial texture due to ion-beam-assisted deposition (IBAD) with an Ar+ ion beam directed at the substrate at a 45 degree angle of inclination. The rock salt layer is typically less than 20 nm in thickness, but shows improved properties as the thickness is reduced further, showing optimal properties for thicknesses between 1 nm and 5 nm. When the etch rate caused by the Ar+ ion beam is nearly in parity with the deposition rate of the MgO or TiN rock salt layer (e.g. when the net deposition rate is less than ten per cent of the deposition rate without use of the IBAD etch beam), the facet spread of overlaid thin films both perpendicular to the film plane and within the film plane is minimized. This dual ion beam approach introduces some remnant stress into the film and benefits from a stress-reducing thermal anneal step. At CMOS compatible temperatures of 400 C, adequate reduction in stress and corresponding surface roughness are reduced significantly. A Cr buffer layer provides good adhesion and a low-roughness interface with the rock salt layer, with narrow crystallite orientation spread for buffer layers in excess of 10 nm, but typically between 15 nm and 45 nm in thickness. The Cr buffer layer is typically deposited using direct current magnetron sputtering, and can be deposited at ambient temperature or at temperatures upwards of CMOS-compatible temperatures of 400 C. We find advantageous performance for 350 C deposited Cr layers, leaving a flat and relaxed surface for deposition of epitaxial functional devices.

### Example 4

An ultrathin ion beam sputtered MgO or TiN rock salt layer 204 inherits biaxial texture due to ion-beam-assisted deposition (IBAD) with an Ar+ ion beam directed at the substrate at a 45 degree angle of inclination. The rock salt layer is 5 nm thick. The etch rate caused by the Ar+ ion beam is 95% of the deposition rate of the MgO or TiN rock salt layer, leading to the facet spread of overlaid thin films both perpendicular to the film plane and within the film plane to be minimized (as shown by the overlaid Cr buffer layer 205 x-ray diffraction data in FIGS. 10 and 11). This dual ion beam approach introduces some remnant stress into the film and benefits from a stress-reducing thermal anneal step. At CMOS compatible temperatures of 400 C, adequate reduction in stress and corresponding surface roughness are reduced significantly. A Cr buffer layer provides good adhesion and a low-roughness interface with the rock salt layer, with narrow crystallite orientation spread for a 30 nm thick buffer layer grown by direct current magnetron sputtering. We find advantageous performance for Cr layers that experience a 350 C microstructural improvement anneal, leaving a flat and relaxed surface for deposition of epitaxial functional devices. An additional Pt buffer layer (5 nm thick) is deposited to inherit the texture of the Cr buffer and adhesion layer but to additionally reduce the lattice mismatch with the buffer layers and an Fe-Pd alloy intermetallic spintronic layer, whose lattice constant is much closer (<3% mismatch) to Pt than to Cr or MgO (both approximately 10% mismatch). The Fe—Pd alloy intermetallic is grown to a thickness ranging from 2 nm up to 16 nm, but typically is set at 8 nm and demonstrates advantageous spintronic properties, including large magneto-crystalline anisotropy for non-volatile spintronic memory and logic devices, low dynamic magnetic losses for energy efficient magnetic bit writing, and is well lattice matched with Heusler allow Co2MnSi, enabling bilayered spintronic functional epitaxial layers, with a 2 nm thick Co2MnSi layer grown above the Fe—Pd alloy to realize large spin polarization for fast, low energy bit read operations when integrated into a magnetic tunnel junction.

The processes described herein may be embodied in, and fully automated via, software code modules executed by a computing system that includes one or more general purpose computers or processors. The code modules may be stored in any type of non-transitory computer-readable medium or other computer storage device. Some or all the methods may alternatively be embodied in specialized computer hardware. In addition, the components referred to herein may be implemented in hardware, software, firmware, or a combination thereof.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

Any logical blocks, modules, and algorithm elements described or used in connection with the embodiments disclosed herein can be implemented as electronic hardware, computer software, or combinations of both. To clearly illustrate this interchangeability of hardware and software, various illustrative components, blocks, modules, and elements have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described or used in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix(s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

### Parts List

epitaxially-grown memory device 200
CMOS wafer 201
contact electrode 202
bottom electrode contact 203
rock salt layer 204 // rock salt layers 204
buffer layers 205
epitaxial functional layers 206
top electrode contact 207
insulating dielectric 208
selector layer 209
via 210

What is claimed is:

1. An epitaxially-grown memory device 200 comprising: a CMOS wafer; a plurality of contact electrodes making electrical contact to metallized VIAs and disposed at a surface of the CMOS wafer; a bottom electrode contact making electrical contact to one of the plurality of contact electrodes and also disposed at the surface of the CMOS wafer; a rock salt layer formed above the bottom electrode; a buffer layer grown above the rock salt layer; an epitaxial functional layer grown above the buffer layer; a top electrode contact grown above the epitaxial functional layer and configured to convey electrical signals to one of the plurality of contact electrodes; and an insulating dielectric formed between the top electrode contact and the bottom electrode contact.

2. The epitaxially-grown memory device 200 of claim 1, wherein the rock salt layer is formed with a fiber texture.

3. The epitaxially-grown memory device 200 of claim 1, wherein the rock salt layer is formed with a biaxial texture.

4. The epitaxially-grown memory device 200 of claim 1, wherein the rock salt layer comprises a first rock salt layer formed with a fiber texture and a second rock salt layer formed above the first rock salt layer.

5. The epitaxially-grown memory device 200 of claim 4, wherein the second rock salt layer is formed of the same material as the first rock salt layer.

6. The epitaxially-grown memory device 200 of claim 1, wherein the buffer layer inherits a texture from the rock salt layer.

7. The epitaxially-grown memory device 200 of claim 1, wherein the epitaxial functional layer inherits a texture from the buffer layer.

8. The epitaxially-grown memory device 200 of claim 1, wherein the epitaxial functional layer is formed of a spintronic material.

9. The epitaxially-grown memory device 200 of claim 1, wherein the epitaxial functional layer is formed of a ferroelectric material.

10. The epitaxially-grown memory device 200 of claim 1, wherein the epitaxial functional layer is formed of a resistive switching material.

11. The epitaxially-grown memory device 200 of claim 1, wherein the epitaxially-grown memory device 200 has the properties of a two-terminal resistive device.

12. The epitaxially-grown memory device 200 of claim 1, further comprising a second epitaxially-grown memory device 200 that is formed on the same CMOS wafer and does not include a rock salt layer.

13. The epitaxially-grown memory device 200 of claim 12, wherein the second epitaxially-grown memory device 200 is configured to have a perpendicular magnetization orientation relative to the epitaxially-grown memory device 200 that includes the rock salt layer.

14. The epitaxially-grown memory device 200 of claim 13, wherein the epitaxially-grown memory device 200 and the second epitaxially-grown memory device 200 are configured to form a magnonic crystal device.

15. The epitaxially-grown memory device 200 of claim 12, wherein the epitaxially-grown memory device 200 and the second epitaxially-grown memory device 200 are configured to have different resistance levels.

16. A method for making a epitaxially-grown memory device 200, the method comprising: providing a CMOS wafer; forming a plurality of contact electrodes on a surface of the CMOS wafer; forming a bottom electrode contact on the surface of the CMOS wafer and in electrical contact with one of the plurality of contact electrodes; forming a rock salt layer above the bottom electrode contact; growing a buffer layer above the rock salt layer; growing an epitaxial functional layer above the buffer layer; forming a top electrode contact above the epitaxial functional layer and configured to convey electrical signals to one of the plurality of contact electrodes; and forming an insulating dielectric between the top electrode contact and the bottom electrode contact.

17. The method of claim 16, wherein forming the rock salt layer includes forming the rock salt layer with a fiber texture.

18. The method of claim 16, wherein growing the buffer layer includes growing the buffer layer to inherit a texture of the rock salt layer.

19. The method of claim 16, wherein growing the epitaxial functional layer includes growing the epitaxial functional layer to inherit a texture of the buffer layer.

20. The method of claim 16, further comprising forming a second epitaxially-grown memory device 200 that does not include a rock salt layer on the same CMOS wafer as the epitaxially-grown memory device 200.
